(19) United States
(12) Patent Application Publication
(10) Pub. No.: US 2024/0030291 A1
(43) Pub. Date: Jan. 25, 2024

(54) SEMICONDUCTOR DEVICE AND METHOD OF FABRICATING THE SAME

(71) Applicant: Samsung Electronics Co., Ltd., Suwon-si (KR)

(72) Inventor: SUNGMIN KIM, Suwon-si (KR)

(21) Appl. No.: 18/125,512

(22) Filed: Mar. 23, 2023

(30) Foreign Application Priority Data
Jul. 21, 2022 (KR) 10-2022-0090273

(51) Int. Cl. H01L 29/10; H01L 27/092; H01L 21/74; H01L 21/8238

(52) U.S. Cl. CPC H01L 29/1083; H01L 27/0924; H01L 21/74; H01L 21/823821; H01L 21/823814; H01L 21/823892

(57) ABSTRACT

Disclosed are semiconductor devices and their fabrication methods. The semiconductor device comprises a substrate provided with an active pattern, a gate electrode that runs across the active pattern and extends in a first direction, source/drain patterns on the active pattern on opposite sides of the gate electrode, a channel pattern formed of a portion of the active pattern between the source/drain patterns, and a buried layer below the source/drain patterns and the channel pattern. The buried layer includes first segments below the source/drain patterns and a second segment below the channel pattern. The first segments have a first level. The second segment has a second level. The first level is lower than the second level.

### CROSS-REFERENCE TO RELATED APPLICATION

This U.S. nonprovisional application claims priority under 35 U.S.0 § 119 to Korean Patent Application No. 10-2022-0090273 filed on Jul. 21, 2022 in the Korean Intellectual Property Office, the disclosure of which is hereby incorporated by reference in its entirety.

### BACKGROUND

The present inventive concepts relate to a semiconductor device (e.g., a semiconductor chip) and a method of fabricating the same, and more particularly, to a semiconductor device including a field effect transistor and a method of fabricating the same.

Semiconductor devices are beneficial in the electronic industry because of their small size, multi-functionality, and/or low fabrication cost. Semiconductor devices may encompass semiconductor memory devices storing logic data, semiconductor logic devices processing operations of logic data, and hybrid semiconductor devices having both memory and logic elements. Semiconductor devices continue to demand high integration with the advanced development of the electronic industry. Furthermore, there continues to be an increased demand for semiconductor devices with high reliability, high speed, and/or multi-functionality. Semiconductor devices continue to become more complicated and more integrated to meet these requested characteristics.

### SUMMARY

Embodiments of the present inventive concepts are directed to a semiconductor device with increased reliability and a method of fabricating the same.

According to some embodiments, a semiconductor device comprises a substrate provided with an active pattern; a gate electrode that runs across the active pattern and extends in a first direction; source/drain patterns on the active pattern on opposite sides of the gate electrode; a channel pattern comprising a portion of the active pattern between the source/drain patterns; and a buried layer below the source/drain patterns and the channel pattern. The buried layer may include first segments below the source/drain patterns; and a second segment below the channel pattern. The first segments may have a first level. The second segment may have a second level. The first level may be lower than the second level.

According to some embodiments, a semiconductor device comprises a substrate that provided with a logic cell including a PMOSFET region and an NMOSFET region that are spaced apart from each other in a first direction; a device isolation layer on the substrate; a first active pattern in the PMOSFET region and a second active pattern in the NMOSFET region, the first and second active patterns extending in a second direction, and an upper portion of each of the first and second active patterns protruding upwardly above the device isolation layer; a gate electrode that extends in the first direction and runs across the first and second active patterns; first source/drain patterns on the first active pattern; second source/drain patterns on the second active pattern; first channel patterns between the first source/drain patterns; second channel patterns between the second source/drain patterns; a buried layer below the first and second source/drain patterns and below the first and second channel patterns; a pair of gate spacers on opposite sidewalls of the gate electrode, the pair of gate spacers extending in the first direction; a gate dielectric layer between the gate electrode and the first and second channel patterns; an interlayer dielectric layer on the gate electrode and the gate spacers; an active contact that penetrates the interlayer dielectric layer and is electrically connected to at least one of the first and second source/drain patterns; and a gate contact that penetrates the interlayer dielectric layer and is electrically connected to the gate electrode. The buried layer may include: first segments below the first and second source/drain patterns; and second segments below the first and second channel patterns. The first segments may have a first level. The second segments may have a second level. The first level may be lower than the second level.

According to some embodiments, a method of fabricating a semiconductor device comprises patterning a substrate to form a plurality of recesses in the surface of the substrate; forming a sacrificial layer on the substrate including in the plurality of recesses; forming a semiconductor layer on the sacrificial layer; patterning the semiconductor layer to form active patterns; forming sacrificial patterns that run across the active patterns and extend in a first direction; forming a corresponding pair of gate spacers on opposite sidewalls of each of the sacrificial patterns; replacing at least some of the sacrificial layer with a buried layer; replacing the sacrificial patterns with a gate electrode; and forming source/drain patterns on the active patterns. The step of forming the pair of gate spacers and replacing the sacrificial layer with the buried layer may be performed at the same time.

### BRIEF DESCRIPTION OF THE DRAWINGS

FIGS. 1 to 3 illustrate conceptual views showing logic cells of a semiconductor device according to some embodiments of the present inventive concepts.

FIG. 4 illustrates a plan view showing a semiconductor device according to some embodiments of the present inventive concepts.

FIGS. 5A, 5B, 5C, 5D, and 5E illustrate cross-sectional views respectively taken along lines A-A′, B-B′, C-C′, D-D′, and E-E′ of FIG. 4, showing a semiconductor device according to some embodiments of the present inventive concepts.

FIGS. 6A to 6E illustrate cross-sectional views taken along line A-A′ of FIG. 4, showing a semiconductor device according to some embodiments of the present inventive concepts.

FIGS. 7 to 14C illustrate cross-sectional views showing a method of fabricating a semiconductor device according to some embodiments of the present inventive concepts.

FIGS. 7, 8, 9, 10, 11A, 12A, 13A, and 14A illustrate cross-sectional views taken along line A-A′ of FIG. 4.

FIGS. 11B, 12B, 13B, and 14B illustrate cross-sectional views taken along line C-C′ of FIG. 4.

FIGS. 11C, 12C, 13C, and 14C illustrate cross-sectional views taken along line D-D′ of FIG. 4.

FIGS. 15 to 18C illustrate cross-sectional views showing a method of fabricating a semiconductor device according to some embodiments of the present inventive concepts.

FIGS. 15, 16A, 17A, and 18A illustrate cross-sectional views taken along line A-A′ of FIG. 4.

FIGS. 16B, 17B, and 18B illustrate cross-sectional views taken along line C-C′ of FIG. 4.

FIGS. 16C, 17C, and 18C illustrate cross-sectional views taken along line D-D′ of FIG. 4.

### DETAILED DESCRIPTION OF EMBODIMENTS

The following will now describe some embodiments of the present inventive concepts with reference to the accompanying drawings. Like reference numerals may indicate like components throughout the description.

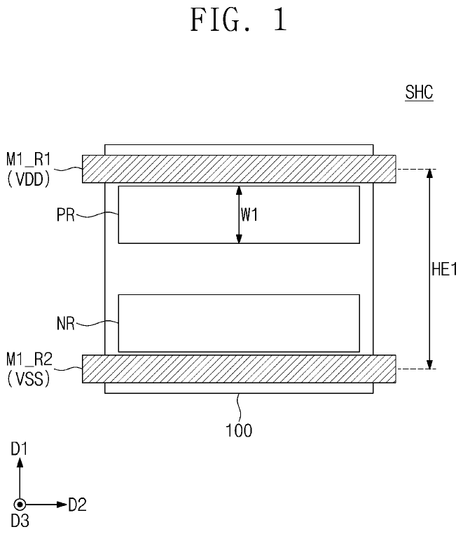

FIGS. 1 to 3 illustrate conceptual views showing logic cells of a semiconductor device (e.g., an integrated circuit of a semiconductor chip) according to some embodiments of the present inventive concepts.

Referring to FIG. 1, a single height cell SHC may be provided. For example, a substrate 100 may be provided thereon with a first power line M1_R1 and a second power line M1_R2. The first power line M1_R1 may be a path for providing a drain voltage VDD, for example, a power voltage. The second power line M1_R2 may be a path for providing a source voltage VSS, for example, a ground voltage. The power lines described herein, such as first and second power lines M1_R1 and M1_R2, may be wires (conductors formed of metal) and connected to corresponding voltage sources (internal voltage regulation circuits of the semiconductor device—not shown) to provide the appropriate voltage (e.g., VDD, VSS, etc.).

The single height cell SHC may be defined between the first power line M1_R1 and the second power line M1_R2. In some examples, the single height cell SHC may include only a single PMOSFET region PR and only a single NMOSFET region NR. The PMOSFET region PR may include one or more PMOS (p-type metal oxide semiconductor) FETs (field effect transistors) formed therein and the NMOSFET region NR may include one or more NMOS (n-type metal oxide semiconductor) FETs formed therein. The PMOSFET regions PR and NMOSFET regions NR described herein may each be an active region defined by corresponding well provided with a substrate in which the corresponding PMOS FETs or NMOS FETs are formed. In some examples, wells defining PMOSFET regions PR may be doped with an n-type charge carrier dopant and wells defining NMOSFET regions NR may be doped with a p-type charge carrier dopant. For example, the single height cell SHC may have a complementary metal oxide semiconductor (CMOS) structure (e.g., formed of interconnected NMOS and PMOS FETs) provided between the first power line M1_R1 and the second power line M1_R2.

In an embodiment, the PMOSFET region PR and the NMOSFET region NR may have the same width in a first direction D1. In another embodiment, the PMOSFET region PR and the NMOSFET region NR may have different widths in the first direction D1. A first height HE1 may denote a length in the first direction D1 of the single height cell SHC. The first height HE1 may be the same as a distance (e.g., pitch) between the first power line M1_R1 and the second power line M1_R2. It will be appreciated that with respect to the description of “height” in connection with a dimension of a cell, such height may extend in a non-vertical direction (e.g., a horizontal direction) with respect to structural descriptions elsewhere herein. For example, direction D3 is often considered a vertical direction (extending away from the surface of a substrate) and directions D1 and D2 are often considered horizontal directions (directions parallel to the upper and lower surfaces of the substrate—e.g., the flat major surfaces of the substrate prior to any processing of the substrate) and such phrasing may be used elsewhere herein to assist in describing certain relationships between various elements. For example, spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures (it will be understood that such spatially relative and directional terms do not restrict the device or other structure to exist in the real world in the particular orientation shown in the figures).

The single height cell SHC may constitute a single logic cell. The logic cell may be a logic device (e.g., a logic gate), such as an AND gate, an OR gate, an XOR gate, an XNOR gate, or an inverter, that performs a specific logic function (e.g., a Boolean function). The logic cell may be formed with transistors and wiring that connect the transistors to each other.

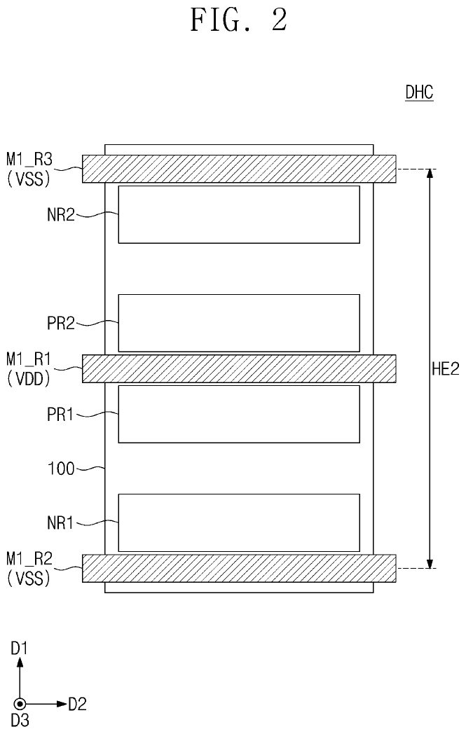

Referring to FIG. 2, a double height cell DHC may be provided. For example, a substrate 100 may be provided thereon with a first power line M1_R1, a second power line M1_R2, and a third power line M1_R3. The first power line M1_R1 may be disposed between the second power line M1_R2 and the third power line M1_R3. The first power line M1_R1 may be a path for providing a drain voltage VDD and the second and third power lines M1_R2 and third power lines M1_R3 may be paths for providing a source voltage VSS.

The double height cell DHC may be defined between the second power line M1_R2 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the second power line M1_R2. The second NMOSFET region NR2 may be adjacent to the third power line M1_R3. The first and second PMOSFET regions PR1 and PR2 may be adjacent to the first power line M1_R1. When viewed in plan, the first power line M1_R1 may be located between the first and second PMOSFET regions PR1 and PR2. Although embodiments described herein illustrate powerlines to be spaced apart (with respect to a top down view) from neighboring NMOSFET regions NR or neighboring PMOSFET regions PR, the embodiments also contemplate that the powerlines may vertically overlap (these neighboring NMOSFET regions NR or neighboring PMOSFET regions PR) and not be spaced apart (with respect to the top down view).

A second height HE2 may be defined to indicate a length in the first direction D1 of the double height cell DHC. The second height HE2 may be about twice the first height HE1 of FIG. 1. The first and second PMOSFET regions PR1 and PR2 of the double height cell DHC may collectively operate as a single PMOSFET region.

Therefore, the double height cell DHC may have a PMOS transistor whose channel size is greater than that of a PMOS transistor included in the single height cell SHC discussed above in FIG. 1. For example, the channel size of the PMOS transistor included in the double height cell DHC may be about twice that of the PMOS transistor included in the single height cell SHC. Thus, the double height cell DHC may operate at a higher speed than that of the single height cell SHC. In the present inventive concepts, the double height cell DHC shown in FIG. 2 is considered as one example of a multi-height cell. Although not shown, a multi-height cell may be a triple height cell whose cell height is about three times that of the single height cell SHC.

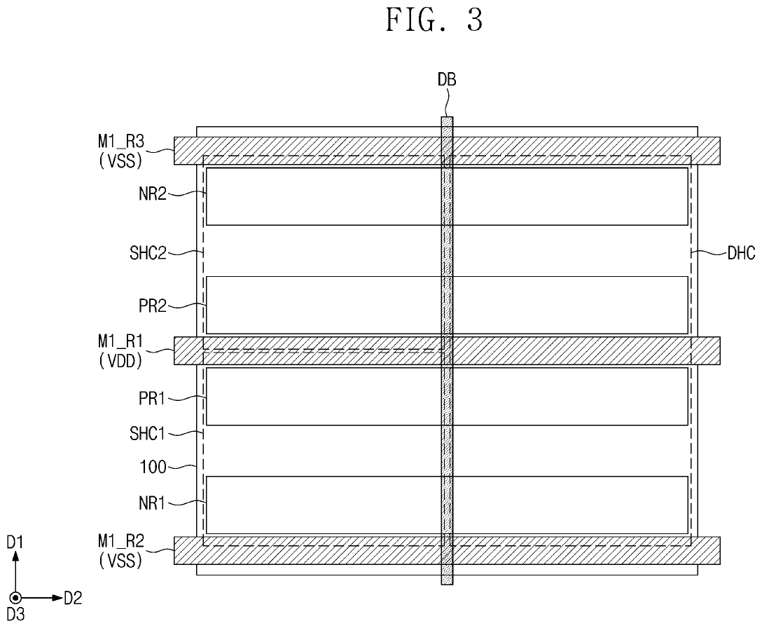

Referring to FIG. 3, a substrate 100 may be provided thereon with a first single height cell SHC1, a second single height cell SHC2, and a double height cell DHC that are two-dimensionally disposed. The first single height cell SHC1 may be located between a first power line M1_R1 and a second power line M1_R2. The second single height cell SHC2 may be located between the first power line M1_R1 and a third power line M1_R3. The second single height cell SHC2 may be adjacent in a first direction D1 to the first single height cell SHC1.

The double height cell DHC may be disposed between the second power line M1_R2 and the third power line M1_R3. The double height cell DHC may be adjacent in a second direction D2 to the first and second single height cells SHC1 and SHC2.

A separation structure DB may be provided between the first single height cell SHC1 and the double height cell DHC and between the second single height cell SHC2 and the double height cell DHC. The separation structure DB may electrically separate an active region of the double height cell DHC from an active region of each of the first and second single height cells SHC1 and SHC2.

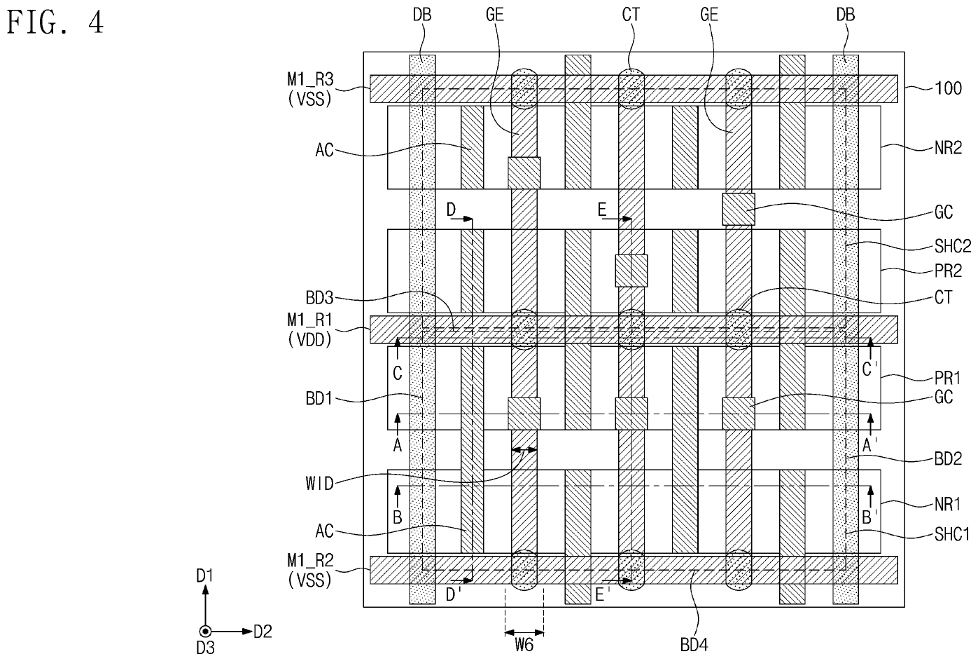

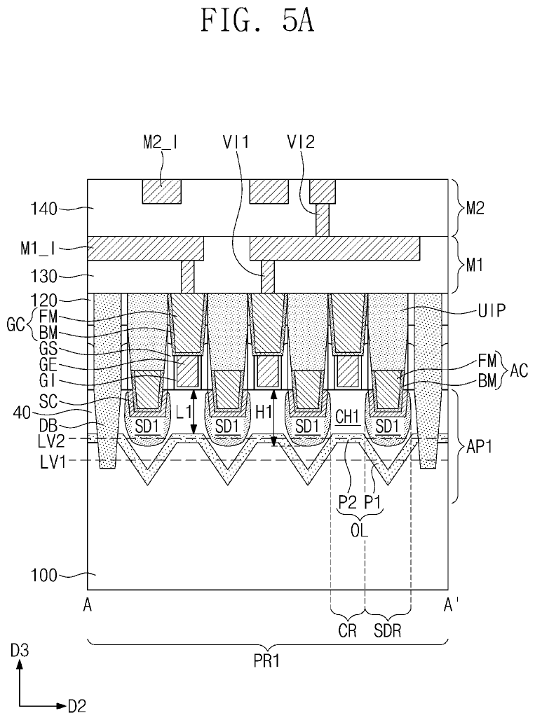

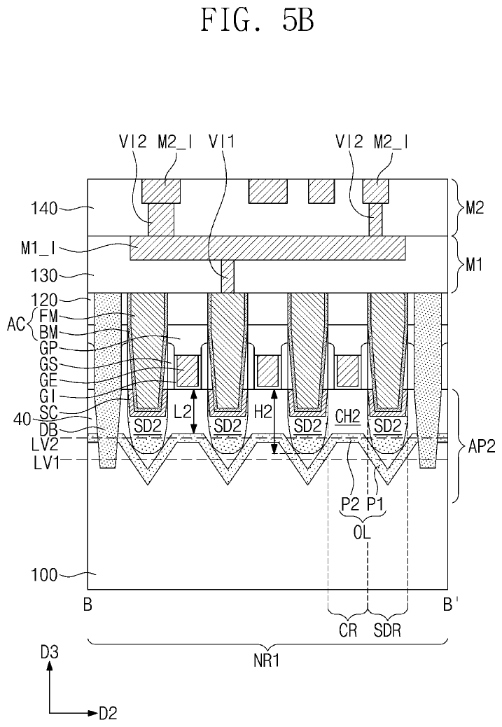

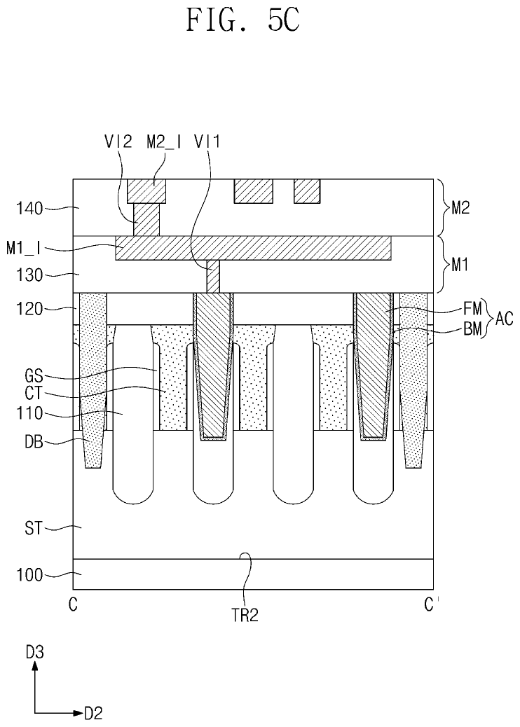

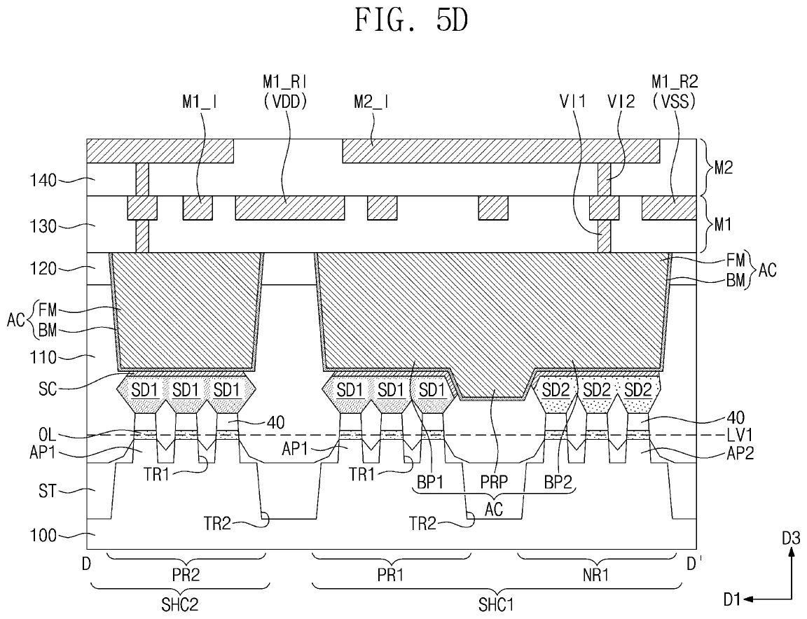

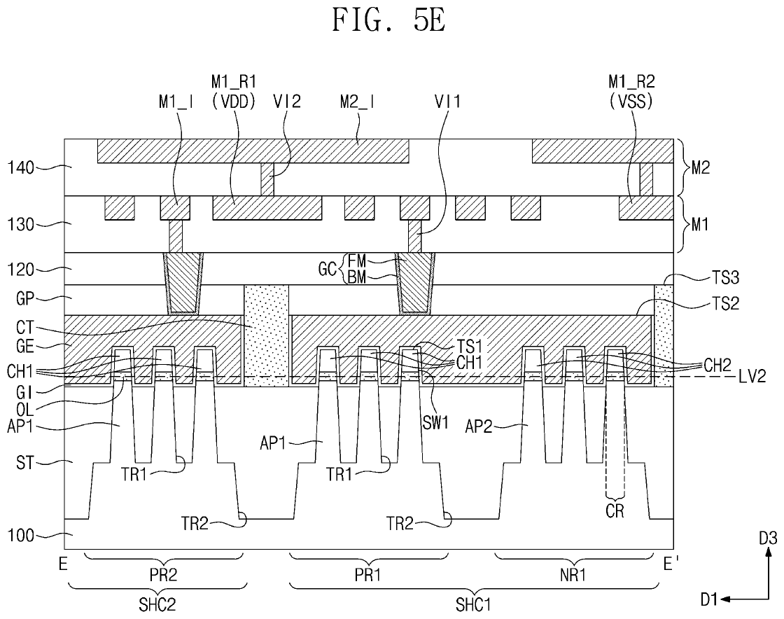

FIG. 4 illustrates a plan view showing a semiconductor device according to some embodiments of the present inventive concepts. FIGS. 5A, 5B, 5C, 5D, and 5E illustrate cross-sectional views respectively taken along lines A-A′, B-B′, C-C′, D-D′, and E-E′ of FIG. 4.

A semiconductor device shown in FIGS. 4 and 5A to 5E is a detailed example of the first and second single height cells SHC1 and SHC2 of FIG. 3. It should be appreciated that the details of the following embodiments that are described in the context of single height cells is also applicable to multi-height cells (e.g., DHC of FIG. 2 or FIG. 3), noting that logic gates of such a multi-height cell may formed via interconnecting transistors formed from the plural NR and PR regions of such a multi-height cell.

Referring to FIGS. 4 and 5A to 5E, first and second single height cells SHC1 and SHC2 may be provided on a substrate 100. Each of the first and second single height cells SHC1 and SHC2 may include transistors interconnected to form a logic circuit (e.g., a logic gate). The substrate 100 may be a compound semiconductor substrate (e.g., formed of several layers, such as semiconductor-on-insulator, such as silicon-on-insulator) or a bulk semiconductor substrate formed of a crystalline material, such as silicon, germanium, or silicon-germanium. For example, the substrate 100 may be a crystalline silicon substrate.

The substrate 100 may have a first PMOSFET region PR1, a second PMOSFET region PR2, a first NMOSFET region NR1, and a second NMOSFET region NR2. Each of the first PMOSFET region PR1, the second PMOSFET region PR2, the first NMOSFET region NR1, and the second NMOSFET region NR2 may extend in a second direction D2. “Extend” in this context refers to the larger horizontal dimension of the region. In general, “extend” may be used to refer to the direction of the largest dimension of an object and/or the larger dimension of the object as it is depicted in two dimensions in a figure being discussed.

A second trench TR2 formed within an upper portion of the substrate 100 may define the first PMOSFET region PR1, the second PMOSFET region PR2, the first NMOSFET region NR1, and the second NMOSFET region NR2. For example, the second trench TR2 may be positioned between the first NMOSFET region NR1 and the first PMOSFET region PR1. The second trench TR2 may be positioned between the first PMOSFET region PR1 and the second PMOSFET region PR2. The second trench TR2 may be positioned between the second PMOSFET region PR2 and the second NMOSFET region NR2. The second trench TR2 may be formed in the upper portion of the substrate 100 to form protruding portions of the substrate 100 forming and surrounding the active regions of each of the first PMOSFET region PR1, the second PMOSFET region PR2, the first NMOSFET region NR1, and the second NMOSFET region NR2 (such active regions having the corresponding first active patterns AP1 and second active patterns AP2 formed therein).

First active patterns AP1 may be provided with each of the first and second PMOSFET regions PR1 and PR2. Second active patterns AP2 may be provided with each of the first and second NMOSFET regions NR1 and NR2.

The first and second active patterns AP1 and AP2 may extend in parallel in the second direction D2. The first and second active patterns AP1 and AP2 may be vertically protruding portions of the substrate 100. First trenches TR1 may be provided between neighboring first active patterns AP1 and between neighboring second active patterns AP2. Each first trench TR1 may be shallower than the second trench TR2. The first and second active patterns AP1 and AP2 may be provided in the protruding active regions of the various regions PR1, PR2, NR1, NR2 and defined by the first trenches TR1 formed therebetween with a buried layer OL which will be discussed below.

A device isolation layer ST may fill the first and second trenches TR1 and TR2. The device isolation layer ST may be and/or include a silicon oxide layer. The first and second active patterns AP1 and AP2 may have their upper portions that vertically protrude above the upper surface of the device isolation layer ST. The first and second active patterns AP1 and AP2 may each have a fin shape at the upper portion thereof. The device isolation layer ST may not cover the upper portions of the first active patterns AP1 nor the upper portions of the second active patterns AP2. The device isolation layer ST may cover lower sidewalls of each of the first and second active patterns AP1 and AP2. The device isolation layer ST may be positioned beneath a buried layer OL which will be discussed below.

First source/drain patterns SD1 may be provided with each of the first and second PMOSFET regions PR1 and PR2. The first source/drain patterns SD1 may be provided on the upper portions of the first active patterns AP1. The first source/drain patterns SD1 may be impurity regions having a first conductivity type (e.g., p-type). A first channel pattern CH1 may be interposed between a pair of first source/drain patterns SD1 that are adjacent to each other in the second direction D2.

Second source/drain patterns SD2 may be provided with each of the first and second NMOSFET regions NR1 and NR2. The second source/drain patterns SD2 may be provided on the upper portion of each of the second active patterns AP2. The second source/drain patterns SD2 may be impurity regions having a second conductivity type (e.g., n-type). A second channel pattern CH2 may be interposed between a pair of second source/drain patterns SD2 that are adjacent to each other in the second direction D2.

The first and second source/drain patterns SD1 and SD2 may be crystalline semiconductor and may be epitaxial patterns formed by a selective epitaxial growth process. In some examples, the first and second source/drain patterns SD1 and SD2 may have their top surfaces coplanar with those of the first and second channel patterns CH1 and CH2. In other examples, the first and second source/drain patterns SD1 and SD2 may have their top surfaces higher than those of the first and second channel patterns CH1 and CH2.

The first source/drain pattern SD1 may be formed of a crystalline semiconductor material (e.g., SiGe) whose lattice constant is greater than that of the crystalline semiconductor material of the substrate 100. Therefore, a pair of first source/drain patterns SD1 may provide a compressive stress to the first channel pattern CH1 therebetween. The second source/drain pattern SD2 may be formed of the same crystalline semiconductor material (e.g., Si) as that of the substrate 100.

Gate electrodes GE may be provided to extend in a first direction D1, while running across the first and second active patterns AP1 and AP2. The gate electrodes GE may be arranged at a first pitch along the second direction D2. The gate electrodes GE may vertically overlap the first and second channel patterns CH1 and CH2. Each of the gate electrodes GE may extend along the top surface and opposite sidewalls of each of the first and second channel patterns CH1 and CH2. The gate electrodes GE may be separated from the top surface and opposite sidewalls of each of the first and second channel patterns CH1 and CH2 by a gate dielectric layer GI.

The gate electrode GE may be provided on a first top surface TS1 and at least one lateral surface SW (e.g., a sidewall) of one or more of the channel patterns CH1 and CH2. In this sense, a transistor according to the present embodiment may be a three-dimensional field effect transistor (e.g., FinFET) in which the gate electrode GE extends three-dimensionally about the corresponding first and second channel patterns CH1 and CH2.

Referring to FIGS. 5A and 5B, a buried layer OL may be provided beneath the gate electrodes GE and the first and second source/drain patterns SD1 and SD2. The first and second channel patterns CH1 and CH2 may be positioned between the gate electrodes GE and the buried layer OL. The buried layer OL may be formed in the first and second channel patterns CH1 and CH2. The first and second source/drain patterns SD1 and SD2 may be positioned between the buried layer OL and active contacts AC which will be discussed below. The buried layer OL may be formed in the first and second active patterns AP1 and AP2. The buried layer OL may prevent and/or reduce the occurrence of a leak current between a bottom surface of the substrate 100 and elements of the FinFET (e.g., source/drain patterns SD1, SD2, and/or channel patterns CH1 and CH2), and thus a semiconductor device may improve in performance. In addition, a parasitic capacitance between the substrate 100 and the first and second source/drain patterns SD1 and SD2 may be reduced by the buried layer OL to improve performance of a semiconductor device.

The buried layer OL may include first segments P1 at a source/drain region locations SDR and second segments P2 at a channel region locations CR. This description refers to source/drain region locations SDR as those regions occupied by, directly above and directly below (i.e., in the third direction D3) a corresponding source/drain pattern (e.g., SD1 or SD2) (i.e., a source/drain region location SDR refers to the three dimensional space corresponding to regions of the semiconductor device within the footprint of a source/drain pattern (the outer boundary of a source/drain pattern as viewed from a top down perspective (i.e., in the third direction D3)). This description refers to channel region locations CR as the regions occupied by a corresponding channel pattern (e.g., CH1 or CH2) between adjacent source/drain region locations SDR and those regions directly above and directly below such regions. A channel region location CR may thus correspond to regions of the semiconductor device within the footprint of a channel region pattern (excluding those portions which may be part of a source/drain region location). First segments P1 of the buried layer OL may correspond to a portion of the buried layer OL within a corresponding source/drain region location SDR (i.e., extending across a corresponding source/drain region location SDR and terminating at opposite boundaries of the corresponding source/drain region location SDR). Furthermore, each of the second segments P2 of the buried layer OL may correspond to a portion of the buried layer OL within a corresponding channel region location CR (i.e., extending across a corresponding channel region location CR and terminating at opposite boundaries of the corresponding channel region location CR). The first segments P1 may have a first level LV1, and the second segments P2 may have a second level LV2. In this description, the term “level” may be an average of the heights of the first and second segments P1 and P2 in a third direction D3 away from the bottom surface of the substrate 100. The first level LV1 of the first segments P1 may be lower than the second level LV2 of the second segments P2. For example, the buried layer OL may be a single continuous layer that is uneven (e.g., undulates up and down). The first segments P1 may have wedge shapes with its apex directed downwardly, toward the bottoms of the first and second active patterns API and AP2. The first segments P1 may have inclined surfaces relative to the horizontal direction (e.g., inclined with respect to the D2 direction) and may be inclined with respect to the bottom surface of the substrate 100. The first segments P1 may have widths that decrease with increasing distance in the third direction D3 from the first and second source/drain patterns SD1 and SD2 (i.e., a width in the D2 direction that decreases with respect to the downward direction with respect to FIG. 5A). The second segments P2 may have convex shapes that protrude upwardly toward the gate electrodes GE. In some examples, portions of the second segments P2 may be substantially flat and extend in the horizontal direction D2.

The buried layer OL may be conformal and thus have a constant thickness. In general, unless context indicates otherwise, “thickness” is used herein to describe the smallest dimension of an object and/or the smaller dimension of an object as it is depicted in two dimensions in a figure being discussed. Thus, the thickness of a layer often refers to the dimension of the layer perpendicular to its major surfaces (e.g., perpendicular to upper and lower surfaces of a layer). It should be appreciated that an object may have several different thickness (i.e., its minimal thickness would not necessarily represent the thickness of an object throughout the entire object). The buried layer OL may have a thickness ranging from about 1 nm to about 20 nm. The buried layer OL may be formed at least one selected from SiCN, SiCON, and SiN. The buried layer OL may be formed of the same material and/or same layer(s) as that of gate spacers GS which will be discussed below. When each of gate spacers GS has a multi-layered structure including a first gate spacer and a second gate spacer, the buried layer OL may include the same multi-layer material as that of the first gate spacer.

A first length L1 may be provided between a top surface of the first active pattern AP1 and top surfaces of the second segments P2 on the first PMOSFET region PR1. A second length L2 may be provided between a top surface of the second active pattern AP2 and top surfaces of the second segments P2 on the first NMOSFET region NR1. The first length L1 may be the same as the second length L2. The first source/drain patterns SD1 may have a first height H1 in the third direction D3 between an uppermost surface of the first active pattern AP1 and lowermost surfaces of the first source/drain patterns SD1. The second source/drain patterns SD2 may have a second height H2 in the third direction D3 between an uppermost surface of the second active pattern AP2 and lowermost surfaces of the second source/drain patterns SD2. The first height H1 may be the same as the second height H2. The first and second heights H1 and H2 may be greater than the first and second lengths L1 and L2.

As the second segments P2 are positioned higher than the first segments P1, it may be possible to allow the first segments P1 to be spaced apart from the first and second source/drain patterns SD1 and SD2 while increasing the vertical lengths of the first and second source/drain patterns SD1 and SD2. Cracks may be prevented from occurring due to contact between a dielectric material and the first and second source/drain patterns SD1 and SD2. For example, because the buried layer OL is positioned spaced apart from the first and second source/drain patterns SD1 and SD2, the semiconductor device may improve in its performance.

Although not shown, the buried layer OL may be provided only inn PMOSFET regions (e.g., only in regions PR1 and PR2) or only in NMOSFET regions (e.g., only in regions NR1 and NR2).

Referring to FIGS. 5D and 5E, portions of the buried layer OL may be spaced apart in the first direction D1 from each other by the first and second trenches TR1 and TR2. The buried layer OL may be positioned between the substrate 100 and a semiconductor layer 40. The portions of the buried layer OL may be formed in each of the first and second active patterns AP1 and AP2. A shown in FIG. 5E, second segments P2 of the buried layer OL may be positioned at a higher level than that of a bottom surface of the gate electrode GE. For example, the top surface or both the top surface and bottom surfaces of the buried layer OL may be positioned at a higher level than the level of the bottom surface of the gate electrode GE.

Referring back to FIGS. 4 and 5A to 5E, the first single height cell SHC1 may have a first boundary BD1 and a second boundary BD2 that are opposite to each other in the second direction D2. The first and second boundaries BD1 and BD2 may extend in the first direction D1. The first single height cell SHC1 may have a third boundary BD3 and a fourth boundary BD4 that are opposite to each other in the first direction D1. The third and fourth boundaries BD3 and BD4 may extend in the second direction D2.

Gate cutting patterns CT may be disposed on one or more boundaries parallel to the second direction D2 of each of the first and second single height cells SHC1 and SHC2. For example, the gate cutting patterns CT may be located on the third and fourth boundaries BD3 and BD4 of the first single height cell SHC1. The gate cutting patterns CT may be arranged at the first pitch along the third boundary BD3. The gate cutting patterns CT may be arranged at the first pitch along the fourth boundary BD4. When viewed in plan, the gate cutting patterns CT on the third and fourth boundaries BD3 and BD4 may be located to correspondingly overlap the gate electrodes GE.

Referring to FIG. 5E, the gate cutting pattern CT may extend in the third direction D3 from the device isolation layer ST from a gate capping pattern GP which will be discussed below. A top surface TS3 of the gate cutting pattern CT may be higher than a top surface TS2 of the gate electrode GE. The top surface TS3 of the gate cutting pattern CT may be coplanar with a top surface of the gate capping pattern GP. The gate cutting pattern CT may be and/or include a dielectric material, such as a silicon nitride layer, a silicon oxide layer, or a combination thereof.

The gate cutting pattern CT may separate gate electrodes of different cells that are aligned in the same line. FIG. 4 illustrates the gate electrodes GE of the first single height cell SHC1 being separated from the gate electrodes GE of the second single height cell SHC2 with corresponding gate cutting patterns CT formed at the third boundary BD3 of the first single height cell SHC1 and the adjacent border of the second single height cell SHC2. The gate cutting pattern CT may be interposed between the gate electrode GE on the first single height cell SHC1 and the gate electrode GE on the second single height cell SHC2, which gate electrodes GE are aligned with each other in the first direction D1. For example, the gate cutting patterns CT may divide the gate electrode GE, which extends in the first direction D1, into a plurality of gate electrodes GE.

A pair of gate spacers GS may be located on opposite sidewalls of each of the gate electrodes GE. The gate spacers GS may extend in the first direction D1 along the gate electrodes GE. The gate spacer GS may have a top surface higher than that of the gate electrode GE adjacent thereto. The top surface of the gate spacer GS may be lower than that of a gate capping pattern GP which will be discussed below. The top surface of the gate spacer GS may be higher than that of the gate cutting pattern CT.

The gate spacer GS may be formed of and/or include at least one material selected from SiCN, SiCON, and SiN. In an embodiment of the present inventive concepts, the gate spacer GS may have a multi-layered structure including a first gate spacer and a second gate spacer. The first gate spacer and the second gate spacer may be formed of different materials from each other. For example, the first gate spacer may be SiOCN whose dielectric constant is low, and the second gate spacer may be SiN whose etch resistance is excellent. The first gate spacer may have a dielectric constant less than that of the second gate spacer. A thickness in the second direction D2 of the first gate spacer may be greater than a thickness in the second direction D2 of the second gate spacer.

Referring again to FIGS. 4 and 5A to 5E, a gate capping pattern GP may be provided on each of the gate electrodes GE. The gate capping pattern GP may extend in the first direction D1 along the gate electrode GE. The gate capping pattern GP may include a material having an etch selectivity with respect to first and second interlayer dielectric layers 110 and 120 which will be discussed below. For example, the gate capping pattern GP may be formed of and/or include at least one material selected from SiON, SiCN, SiCON, and SiN.

A gate dielectric layer GI may be interposed between the gate electrode GE and the first active pattern AP1 and between the gate electrode GE and the second active pattern AP2. The gate dielectric layer GI may extend along and contact the bottom surface of the gate electrode GE that overlies the gate dielectric layer GI. For example, the gate dielectric layer GI may extend across and contact the first top surface TS1 and the first lateral surfaces SW1 of the channel pattern CH1 or CH2. The gate dielectric layer GI may extend across and contact a top surface of the device isolation layer ST that underlies the gate electrode GE.

In an embodiment of the present inventive concepts, the gate dielectric layers GI may be and/or include a high-k dielectric material whose dielectric constant is greater than that of a silicon oxide layer. For example, the high-k dielectric material may be formed of one or more of the following materials: hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate. The gate dielectric layer GI may be formed of multiple layers, and may comprise a stack of a silicon oxide layer and a high-k dielectric layer.

Alternatively, a semiconductor device according to the present inventive concepts may include a negative capacitance field effect transistor that uses a negative capacitor. For example, the gate dielectric layer GI may be and/or include a ferroelectric material layer that exhibits ferroelectric properties and/or a paraelectric material layer that exhibits paraelectric properties.

The ferroelectric material layer may have a negative capacitance, and the paraelectric material layer may have a positive capacitance. For example, when two or more capacitors are connected in series, and when each capacitor has a positive capacitance, an overall capacitance may be reduced to be less than the capacitance of each capacitor. In contrast, when at least one of two or more capacitors connected in series has a negative capacitance, an overall capacitance may have a positive value that is increased to be greater than an absolute value of the capacitance of each capacitor.

When the ferroelectric material layer having a negative capacitance is connected in series to the paraelectric material layer having a positive capacitance, there may be an increase in overall capacitance of the ferroelectric and paraelectric material layers that are connected in series. The increase in overall capacitance may be used to form a transistor including the ferroelectric material layer to have a sub-threshold swing of less than about 60 mV/decade at room temperature.

The ferroelectric material layer may have ferroelectric properties. The ferroelectric material layer may be formed of one or more of the following materials: hafnium oxide, hafnium zirconium oxide, barium strontium titanium oxide, and lead zirconium titanium oxide. In some examples, the hafnium zirconium oxide may be doped with zirconium (Zr). In other examples, the hafnium zirconium oxide may be a compound of hafnium (Hf), zirconium (Zr), and oxygen (O).

The ferroelectric material layer may further include impurities doped therein. For example, the impurities may include at least one selected from aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). The type of impurities included in the ferroelectric material layer may be changed depending on what ferroelectric material is included in the ferroelectric material layer.

When the ferroelectric material layer is hafnium oxide, the ferroelectric material layer may include impurities such as gadolinium (Gd), silicon (Si), zirconium (Zr), aluminum (Al), and/or yttrium (Y).

When the impurities are aluminum (Al), the ferroelectric material layer may include about 3 to 8 atomic percent aluminum (the number of aluminum atoms to the sum of the number of hafnium and aluminum atoms).

When the impurities are silicon (Si), the ferroelectric material layer may include about 2 to about 10 atomic percent silicon. When the impurities are yttrium (Y), the ferroelectric material layer may include about 2 to about 10 atomic percent yttrium. When the impurities are gadolinium (Gd), the ferroelectric material layer may include about 1 to about 7 atomic percent gadolinium. When the impurities are zirconium (Zr), the ferroelectric material layer may include about 50 to about 80 atomic percent zirconium.

The paraelectric material layer may have paraelectric properties. The paraelectric material layer may be and/or include, for example, at least one selected from silicon oxide and high-k metal oxide. The metal oxide included in the paraelectric material layer may include, for example, one or more of hafnium oxide, zirconium oxide, and aluminum oxide, but the present inventive concepts are not limited thereto.

The ferroelectric and paraelectric material layers may be formed of the same material. The ferroelectric material layer may have ferroelectric properties, but the paraelectric material layer may not have ferroelectric properties. For example, when the ferroelectric material layer and the paraelectric material layer include hafnium oxide, the hafnium oxide included in the ferroelectric material layer may have a crystal structure different from that of the hafnium oxide included in the paraelectric material layer.

The ferroelectric material layer may have a thickness having ferroelectric properties. The thickness of the ferroelectric material layer may range, for example, from about 0.5 nm to about 10 nm, but the present inventive concepts are not limited thereto. Because ferroelectric materials have their own critical thickness that exhibits ferroelectric properties, the thickness of the ferroelectric material layer may depend on ferroelectric material.

For example, the gate dielectric layer GI may be formed of a single homogenous ferroelectric material layer. In other examples, the gate dielectric layer GI may include a plurality of different ferroelectric material layers that are spaced apart from each other. The gate dielectric layer GI may have a stack structure in which a plurality of ferroelectric material layers are alternately stacked with a plurality of paraelectric material layers.

The gate electrode GE may include a first metal pattern and a second metal pattern on the first metal pattern. The first metal pattern may be provided on the gate dielectric layer GI and may be adjacent to the first and second channel patterns CH1 and CH2. The first metal pattern may include a work-function metal that controls a threshold voltage of a transistor. A thickness and composition of the first metal pattern may be chosen to achieve a desired threshold voltage.

The first metal pattern may be and/or include a metal nitride layer. For example, the first metal pattern may include nitrogen (N) and at least one metal selected from titanium (Ti), tantalum (Ta), aluminum (Al), tungsten (W), and molybdenum (Mo). The first metal pattern may further include carbon (C). The first metal pattern may include a plurality of stacked work-function metal layers.

The second metal pattern may be and/or include metal whose resistance is less than that of the first metal pattern. For example, the second metal pattern may include at least one metal selected from tungsten (W), aluminum (Al), titanium (Ti), and tantalum (Ta).

A first interlayer dielectric layer 110 may be provided on the substrate 100. The first interlayer dielectric layer 110 may cover the gate spacers GS and the first and second source/drain patterns SD1 and SD2. The first interlayer dielectric layer 110 may have a top surface substantially coplanar with that of the gate capping pattern GP.

The first interlayer dielectric layer 110 may be provided thereon with a second interlayer dielectric layer 120 that covers the gate capping patterns GP and the gate cutting patterns CT. A third interlayer dielectric layer 130 may be provided on the second interlayer dielectric layer 120. A fourth interlayer dielectric layer 140 may be provided on the third interlayer dielectric layer 130. For example, the first to fourth interlayer dielectric layers 110 to 140 may include a silicon oxide layer.

Each of the first and second single height cells SHC1 and SHC2 may be provided on its opposite sides with a pair of separation structures DB that are opposite to each other in the second direction D2. For example, the separation structures DB may be correspondingly provided on first and second boundaries BD1 and BD2 of the first single height cell SHC1. The separation structures DB may extend in the first direction D1 parallel to the gate electrodes GE. A pitch between the separation structure DB and its adjacent gate electrode GE may be the same as the first pitch.

The separation structure DB may penetrate the first and second interlayer dielectric layers 110 and 120 to extend into the first and second active patterns AP1 and AP2. The separation structure DB may penetrate the upper portion of each of the first and second active patterns AP1 and AP2. The separation structure DB may penetrate and fully extend through the buried layer OL. The separation structure DB may electrically separate an active region of each of the first and second single height cells SHC1 and SHC2 from a corresponding active region of another cell.

Active contacts AC may be provided to penetrate the first and second interlayer dielectric layers 110 and 120 and to electrically connect to corresponding ones of the first and second source/drain patterns SD1 and SD2. Each of the active contacts AC may be provided between a corresponding pair of neighboring gate electrodes GE. When viewed in plan, each of the active contacts AC may have a linear or bar shape that extends in the first direction D1.

The active contact AC may be a self-aligned contact. For example, the gate capping pattern GP and the gate spacer GS may be used to form the active contact AC in a self-alignment manner. The active contact AC may cover, for example, at least a portion of a sidewall of the gate spacer GS. Although not shown, the active contact AC may cover a portion of the top surface of the gate capping pattern GP.

Silicide patterns SC may be correspondingly interposed between the active contacts AC and the first source/drain patterns SD1 and between the active contacts AC and the second source/drain patterns SD2. The active contacts AC may be electrically connected through the silicide patterns SC to the first and second source/drain patterns SD1 and SD2. The silicide pattern SC may formed of metal silicide, for example, at least one selected from titanium silicide, tantalum silicide, tungsten silicide, nickel silicide, and cobalt silicide.

Referring back to FIG. 5D, at least one active contact AC on the first single height cell SHC1 may electrically connect the first source/drain pattern SD1 of the first PMOSFET region PR1 to the second source/drain pattern SD2 of the first NMOSFET region NR1. The active contact AC may extend in the first direction D1 from the second source/drain pattern SD2 of the first NMOSFET region NR1 to the first source/drain pattern SD1 of the first PMOSFET region PR1. The active contact AC may include a first body BP1 on the first source/drain pattern SD1 and a second body BP2 on the second source/drain pattern SD2. The first body BP1 may be connected through the silicide pattern

SC to a top surface of the first source/drain pattern SD1, and the second body BP2 may be connected through the silicide pattern SC to a top surface of the second source/drain pattern SD2. The active contact AC may further include a protrusion PRP interposed between the first body BP1 and the second body BP2. The protrusion PRP may be provided on the device isolation layer ST between the first PMOSFET region PR1 and the first NMOSFET region NR1.

The protrusion PRP may extend from the first body BP1 toward the device isolation layer ST, while running along an inclined sidewall of the first source/drain pattern SD1. The protrusion PRP may extend from the second body BP2 toward the device isolation layer ST, while running along an inclined sidewall of the second source/drain pattern SD2. The protrusion PRP may have a bottom surface lower than that of each of the first and second bodies BP1 and BP2. The bottom surface of the protrusion PRP may be located higher than the device isolation layer ST. For example, the protrusion PRP may be spaced apart from the device isolation layer ST across the first interlayer dielectric layer 110.

According to an embodiment of the present inventive concepts, the active contact AC may not only be connected through the first body BP1 to the top surface of the first source/drain pattern SD1, but may also be connected through the protrusion PRP to the inclined sidewall of the first source/drain pattern SD1. For example, the protrusion PRP may increase a contact area between the active contact AC and the first source/drain pattern SD1. Therefore, there may be a reduction in resistance between the active contact AC and the first source/drain pattern SD1. Likewise, the protrusion PRP may induce a reduction in resistance between the active contact AC and the second source/drain pattern SD2. Thus, it may be possible to increase an operating speed of a semiconductor device according to some embodiments of the present inventive concepts.

Gate contacts GC may be provided to penetrate the second interlayer dielectric layer 120 and the gate capping pattern GP and to correspondingly electrically connect to the gate electrodes GE. When viewed in plan, the gate contacts GC on the first single height cell SHC1 may be located to overlap the first PMOSFET region PR1. For example, the gate contacts GC on the first single height cell SHC1 may be provided on the first active pattern AP1.

On the gate electrode GE, the gate contact GC may be freely located with no limitation of position. For example, the gate contacts GC on the second single height cell SHC2 may be disposed on the device isolation layer ST that fills the second PMOSFET region PR2, the second NMOSFET region NR2, and the second trench TR2.

The active contact AC may have an upper portion adjacent to the gate contact GC, and an upper dielectric pattern UIP may fill the upper portion of the active contact AC. The upper dielectric pattern UIP may cause the active contact AC adjacent to the gate contact GC to have a top surface lower than a bottom surface of the gate contact GC. This configuration may prevent the occurrence of electrical short caused by contact between the gate contact GC and its adjacent active contact AC.

Each of the active contact AC and the gate contact GC may include a conductive pattern FM and a barrier pattern BM that surrounds the conductive pattern FM. For example, the conductive pattern FM may be and/or include at least one metal selected from aluminum, copper, tungsten, molybdenum, and cobalt. The barrier pattern BM may cover and contact sidewalls and a bottom surface of the conductive pattern FM. The barrier pattern BM may be and/or include a metal layer and a metal nitride layer. The metal layer may include at least one selected from titanium, tantalum, tungsten, nickel, cobalt, and platinum. The metal nitride layer may include at least one selected from a titanium nitride (TiN) layer, a tantalum nitride (TaN) layer, a tungsten nitride (WN) layer, a nickel nitride (NiN) layer, a cobalt nitride (CoN) layer, and a platinum nitride (PtN) layer.

A first metal layer M1 may be provided in the third interlayer dielectric layer 130. For example, the first metal layer M1 may include a first power line M1_R1, a second power line M1_R2, a third power line M1_R3, and first wiring lines M1_I. The lines M1_R1, M1_R2, M1_R3, and M1_I of the first metal layer M1 may extend parallel to each other in the second direction D2.

For example, the first and second power lines M1_R1 and M1_R2 may be correspondingly provided on the third and fourth boundaries BD3 and BD4 of the first single height cell SHC1. The first power line M1_R1 may extend in the second direction D2 along the third boundary BD3. The second power line M1_R2 may extend in the second direction D2 along the fourth boundary BD4.

The first wiring lines M1_I of the first metal layer M1 may be arranged at a second pitch along the first direction D1. The second pitch may be less than the first pitch. Each of the first wiring lines M1_I may have a line-width less than that of each of the first, second, and third power lines M1_R1, M1_R2, and M1_R3.

The first metal layer M1 may further include first vias VI1. The first vias VI1 may be correspondingly provided below the lines M1_R1, M1_R2, M1_R3, and M1_I of the first metal layer M1. The first via VI1 may electrically connect the active contact AC to one of the lines M1_R1, M1_R2, M1_R3, and M1_I of the first metal layer M1. The first via VI1 may electrically connect the gate contact GC to one of the lines M1_R1, M1_R2, M1_R3, and M1_I of the first metal layer M1.

A certain line and its underlying first via VI1 of the first metal layer M1 may be formed by individual processes. For example, a wiring line and its underlying first via VI1 of the first metal layer M1 may each be formed by a single damascene process. A sub-20 nm process may be employed to fabricate a semiconductor device according to the present embodiment.

A second metal layer M2 may be provided in the fourth interlayer dielectric layer 140. The second metal layer M2 may include a plurality of second wiring lines M2_I.

The second wiring lines M2_I of the second metal layer M2 may each have a linear or bar shape that extends in the first direction D1. For example, the second wiring lines M2_I may parallel extend in the first direction D1.

The second metal layer M2 may further include second vias VI2 correspondingly provided below the second wiring lines M2_I. A certain line of the first metal layer M1 may be electrically through the second via VI2 to a corresponding line of the second metal layer M2. A wiring line and its underlying second via VI2 of the second metal layer M2 may be simultaneously formed by a dual damascene process.

The first and second metal layers M1 and M2 and their wiring lines may be formed of the same or different conductive materials. For example, the first and second metal layers M1 and M2 and their wiring lines may be formed of at least one metallic material selected from aluminum, copper, tungsten, molybdenum, and cobalt. Although not shown, other metal layers (e.g., M3, M4, M5, etc.) may be additionally stacked on the fourth interlayer dielectric layer 140. Each of the stacked metal layers may include wiring lines for routing between cells.

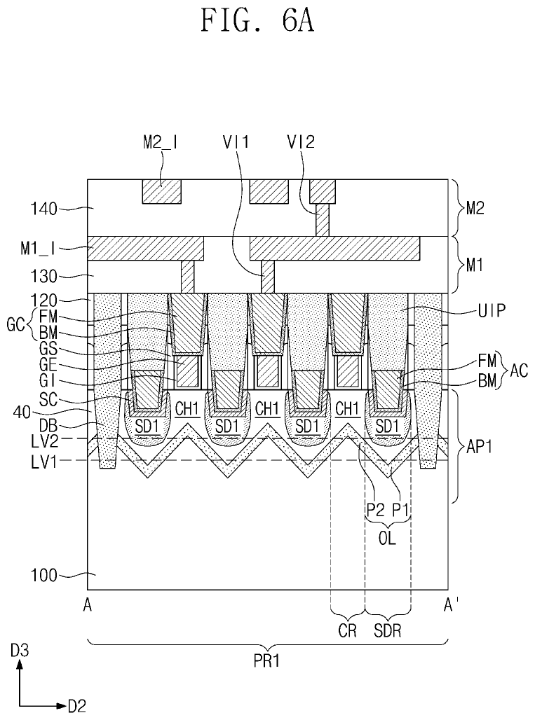

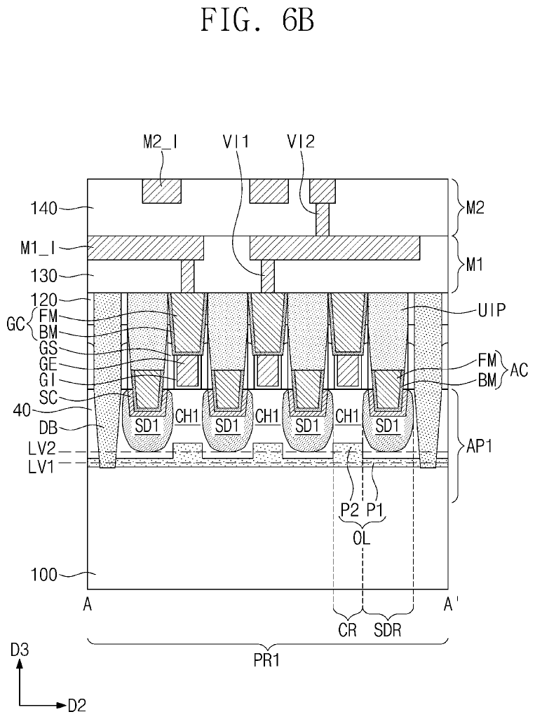

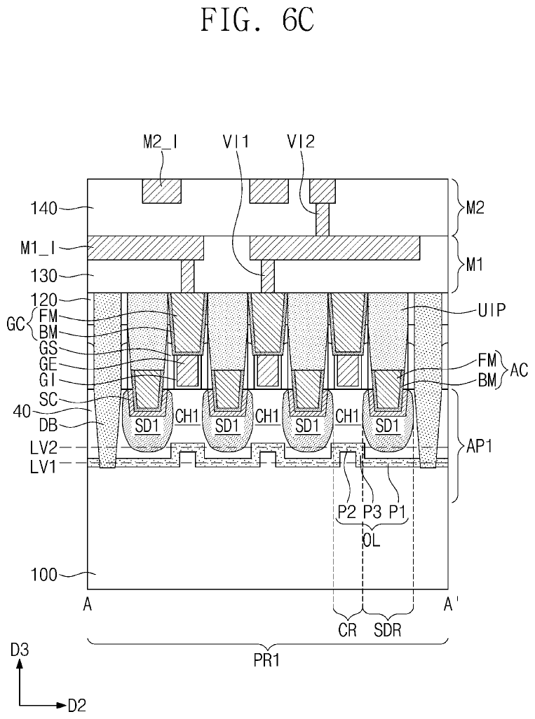

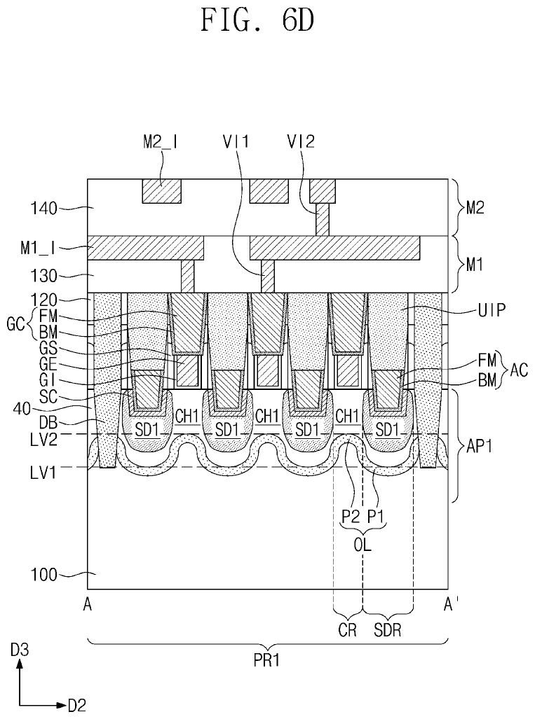

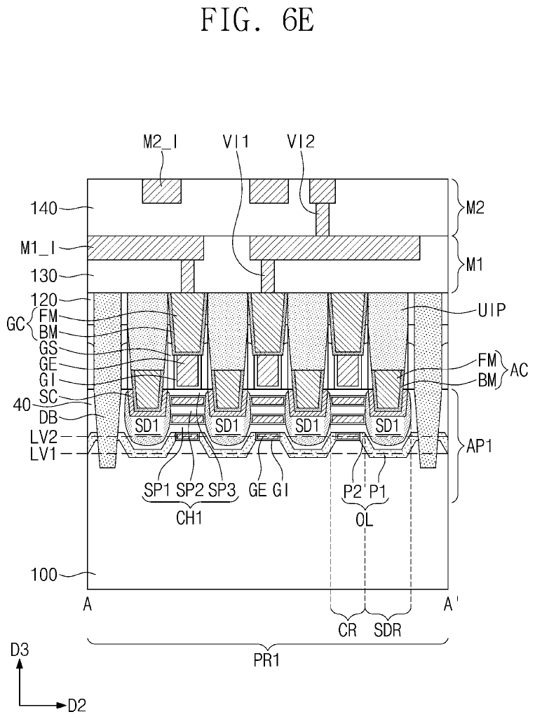

FIGS. 6A to 6E illustrate cross-sectional views taken along line A-A′ of FIG. 4, showing a semiconductor device according to some embodiments of the present inventive concepts.

For convenience of description, a description of the same components as those discussed with reference to FIGS. 5A to 5E may be omitted below, and a difference thereof will be discussed in detail.

Referring to FIGS. 6A to 6E, the buried layer OL may be provided in various forms below the first source/drain patterns SD1. The buried layer OL may be formed such that the first level LV1 of the first segments P1 is lower than the second level LV2 of the second segments P2.

Referring to FIG. 6A, the first segments P1 of the buried layer OL may have a wedge shape directed toward the bottom surface of the first active pattern AP1, and the second segments P2 may have a wedge shape directed toward the top surface of the first active pattern AP1. The first and second segments P1 and P2 may have surfaces inclined with respect to the horizontal direction (e.g., relative to an unetched surface of the substrate 100, such as all or a majority of the bottom surface of the substrate 100). The first segments P1 may have a width (e.g., in the second direction D2) that decreases with increasing distance in the third direction D3 from the first source/drain pattern SD1 (i.e., a horizontal width decreasing with respect to the downward direction). The second segments P2 may have a width (e.g., in the second direction D2) that increases with increasing distance in the third direction D3 from the gate electrode GE (i.e., a horizontal width increasing with respect to the downward direction). For example, the second segments P2 may have a shape symmetric to that of the first segments P1.

Referring to FIG. 6B, the first and second segments P1 and P2 may each have top and bottom surfaces that extend in the horizontal direction and may be flat (e.g., parallel to the bottom surface of the substrate 100). A thickness in the third direction D3 of the first segments P1 may be greater than a thickness in the third direction D3 of the second segments P2. The first and second segments P1 and P2 may have their bottom surfaces located at the same plane. The top surfaces of the first segments P1 may be located at a lower level than that of the top surfaces of the second segments P2.

Referring to FIG. 6C, the buried layer OL may further include third segments P3. The first and second segments P1 and P2 may each have top and bottom surfaces that extend in the horizontal direction and may be flat (e.g., are parallel to the bottom surface of the substrate 100). The first and second segments P1 and P2 may have substantially the same thickness in the third direction D3. The third segments P3 may be positioned between and connect adjacent ones of the first and second segments P1 and P2. The third segments P3 may extend in the vertical direction D3. The buried layer OL may be conformal such that the thickness of the third segments P3 in the second direction D2 is substantially the same as the thickness of the first and second segments P1 and P2 in the third direction D3

Referring to FIG. 6D, the first segments P1 may have a concave shape directed toward the first source/drain patterns SD1 (i.e., with respect to the upward direction). The second segments P2 may have a convex shape directed toward the gate electrode GE (i.e., with respect to the upward direction). For example, the first segments P1 may have a convex shape directed toward the bottom surface of the first active pattern AP1, and the second segments P2 may have a convex shape directed toward the top surface of the first active pattern AP1.

Referring to FIG. 6E, a semiconductor device according to some embodiments of the present inventive concepts may be an integrated circuit including a three-dimensional field effect transistor, or a multi-bridge channel field effect transistor (MBCFET) or a gate all around field effect transistor (GAAFET). The first channel pattern CH1 may include first, second, and third semiconductor patterns SP1, SP2, and SP3 that are sequentially stacked. The first, second, and third semiconductor patterns SP1, SP2, and SP3 may be spaced apart from each other in a vertical direction (or the third direction D3). Each of the first, second, and third semiconductor patterns SP1, SP2, and SP3 may be positioned between vertically spaced portions of the gate electrode GE.

Each of the first, second, and third semiconductor patterns SP1, SP2, and SP3 may be formed of and/or include silicon (Si), germanium (Ge), or silicon-germanium (SiGe). For example, each of the first, second, and third semiconductor patterns SP1, SP2, and SP3 may be formed of crystalline silicon. A portion or entirety of the second segment P2 of the buried layer OL may be formed of the same conductive material as that of the gate electrode GE. The second segment P2 of the buried layer OL may constitute a portion of the gate electrode GE and a portion of the gate dielectric layer GI. For example, differently from that discussed in FIGS. 5A to 5E, the second segments P2 of the buried layer OL may include a material (e.g., a conductive material) different from a dielectric material. Outer portions of the second segment P2 (i.e., at the boundary of the channel region location CR) may be a dielectric material and form a portion of the gate dielectric layer GI and the conductive material may be positioned between these outer portions. The first segments P1 of the buried layer OL may include a dielectric material, such as one or more of SiCN, SiOCN, and SiN. The second segment P2 of the buried layer OL may serve as a gate of a transistor.

The first source/drain patterns SD1 may be provided on the first active pattern AP1. The first, second, and third semiconductor patterns SP1, SP2, and SP3 of the first channel pattern CH1 may be interposed between a pair of neighboring first source/drain patterns SD1. The first, second, and third semiconductor patterns SP1, SP2, and SP3 may connect to each other the pair of neighboring first source/drain patterns SD 1.

The gate electrodes GE may be provided to extend in the first direction D1, while running across the first channel patterns CH1. The gate electrodes GE may vertically overlap the first channel patterns CH1. A pair of gate spacers GS may be disposed on opposite sidewalls of the gate electrode GE. Portions of the gate electrode GE may surround the first, second, and third semiconductor patterns SP1, SP2, and SP3.

The gate dielectric layer GI may be provided between a portion of the gate electrode GE and each of the first, second, and third semiconductor patterns SP1, SP2, and SP3. The gate dielectric layer GI may surround the first channel pattern CH1.

Although not shown, the second channel patterns CH2 of the first NMOSFET region NR1, the second source/drain patterns SD2, the gate electrode GE, and the gate dielectric layer GI may be substantially the same as the first channel patterns CH1, the first source/drain patterns SDI, the gate electrode GE, and the gate dielectric layer GI that are discussed in FIG. 6E.

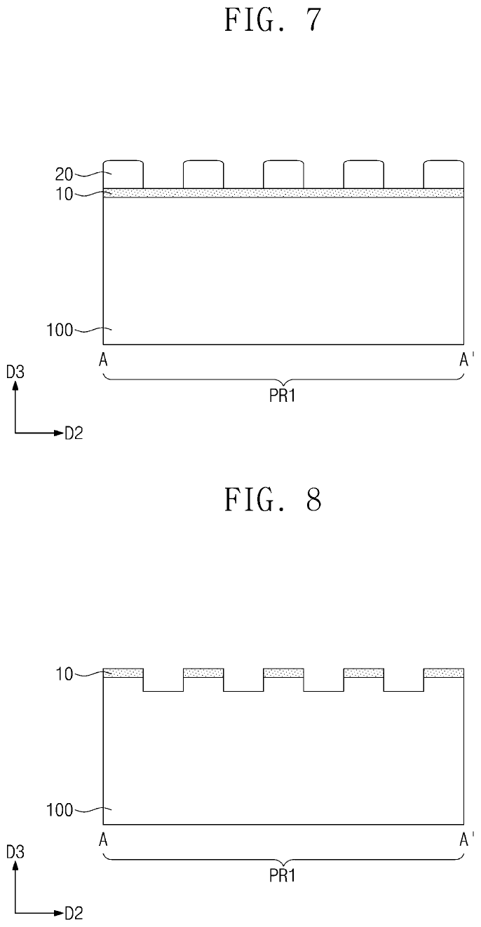

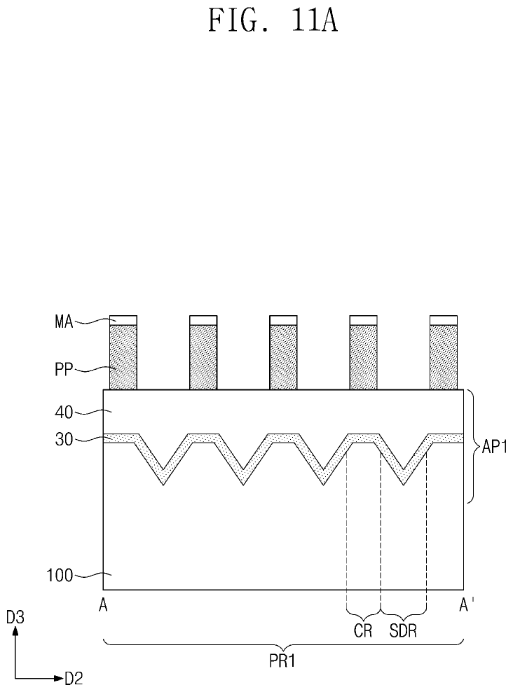

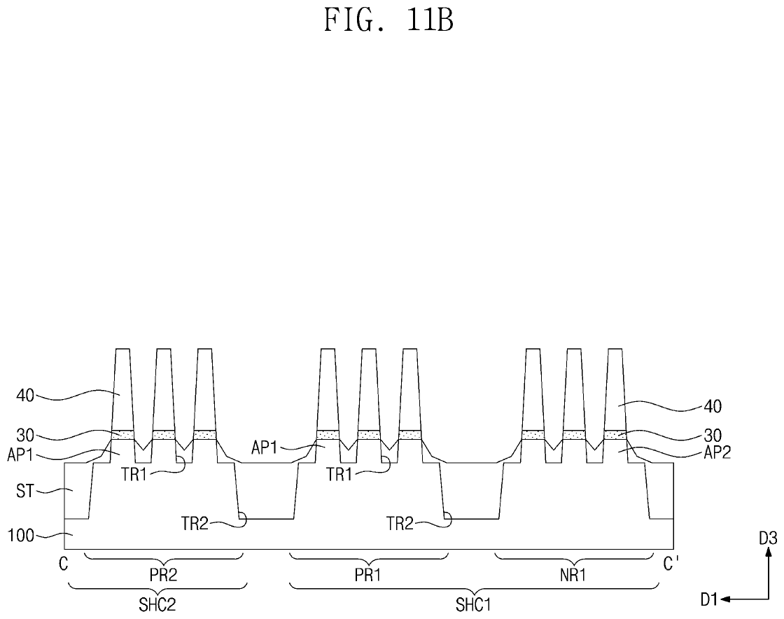

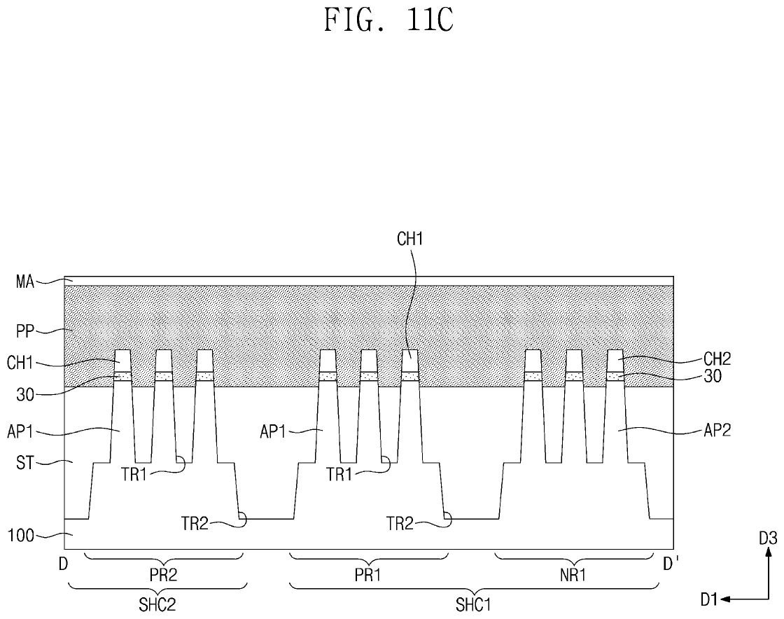

FIGS. 7 to 14C illustrate cross-sectional views showing a method of fabricating a semiconductor device according to some embodiments of the present inventive concepts. FIGS. 7, 8, 9, 10, 11A, 12A, 13A, and 14A illustrate cross-sectional views taken along line A-A′ of FIG. 4. FIGS. 11B, 12B, 13B, and 14B illustrate cross-sectional views taken along line C-C′ of FIG. 4. FIGS. 11C, 12C, 13C, and 14C illustrate cross-sectional views taken along line D-D′ of FIG. 4. The materials referenced in this description of fabricating as semiconductor device may be the same as those described with respect to corresponding portions of the semiconductor device and thus need not be fully repeated.

Referring to FIG. 7, a mask layer 10 may be provided on a substrate 100. The mask layer 10 may be a compound including, for example, one or more of silicon (Si), oxygen (O), carbon (C), and nitrogen (N). The mask layer 10 may include a material having an etch selectivity with respect to the substrate 100.

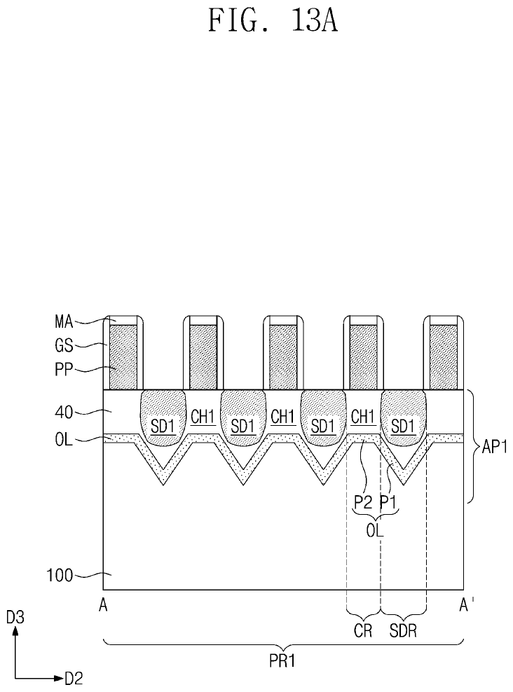

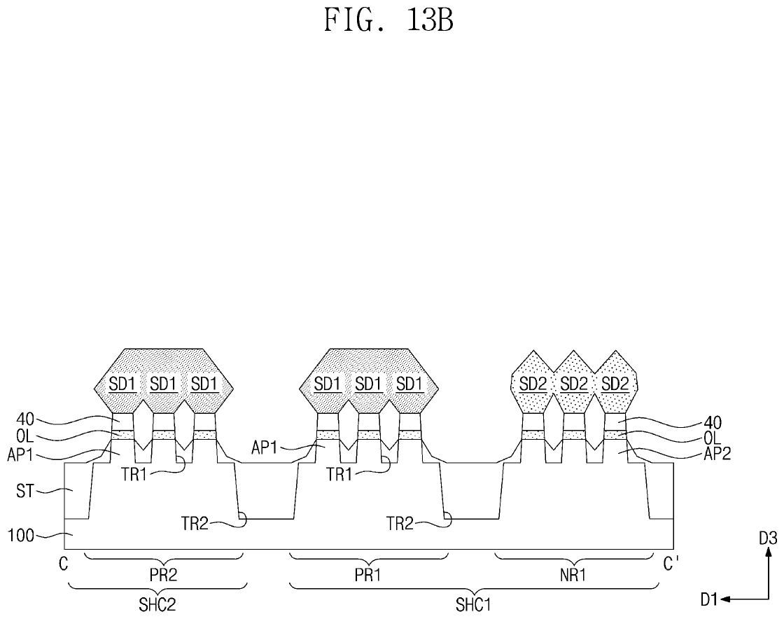

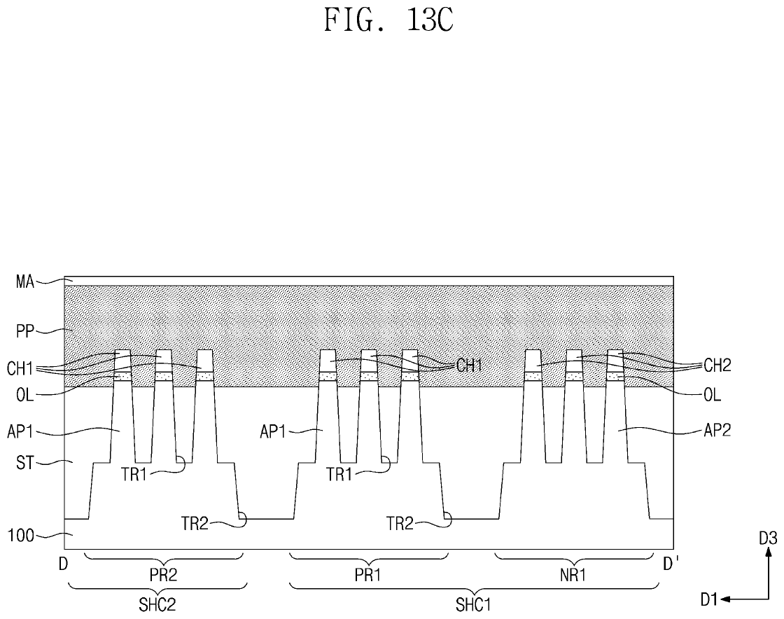

A plurality of photoresist patterns 20 may be provided on the mask layer 10. The photoresist patterns 20 may extend in a first direction D1 and may be spaced apart in a second direction D2. An interval in the second direction D2 of the photoresist patterns 20 may be the same as a distance between gate electrodes (see GE of FIG. 13A) which will be discussed below. An exposure apparatus may be used in exposure and development processes by which a photoresist layer is formed into the photoresist patterns 20. The exposure apparatus may be, for example, an apparatus that uses an extreme ultraviolet (EUV). In this description, the EUV may be ultraviolet light having a wavelength of about 4 nm to about 124 nm, and preferably of about 4 nm to about 20 nm, and more preferably of about 13.5 nm. The EUV may denote light whose energy is in the range of about 6.21 eV to about 124 eV, for example, about 90 eV to about 95 eV. The photoresist layer may be an organic photoresist that contains an organic polymer such as polyhydroxystyrene. The organic photoresist may further include a photosensitive compound sensitive to the EUV. The organic photoresist may additionally include a material whose EUV absorption coefficient is high, for example, an organometallic material, an iodine-containing material, or a fluorine-containing material. In other examples, the photoresist layer may be an inorganic photoresist that contains an inorganic material, such as tin oxide.

Referring to FIG. 8, the photoresist patterns 20 may be used as a mask to perform an etching process. The etching process may be, for example, a dry etching process. The etching process may remove a portion of the mask layer 10. The etching process may convert the mask layer 10 into patterns that extend in the first direction D1 and are spaced apart from each other in the second direction D2. A portion of the mask layer 10 may be removed to expose an upper portion of the substrate 100. While the etching process is performed, not only the mask layer 10 but also an upper portion of the substrate 100 may be partially removed. After the etching process, trenches may be formed in the substrate 100 extending in the first direction and positioned between corresponding pairs of the patterns of the mask layer 10. The trenches may have vertically extending sidewalls.

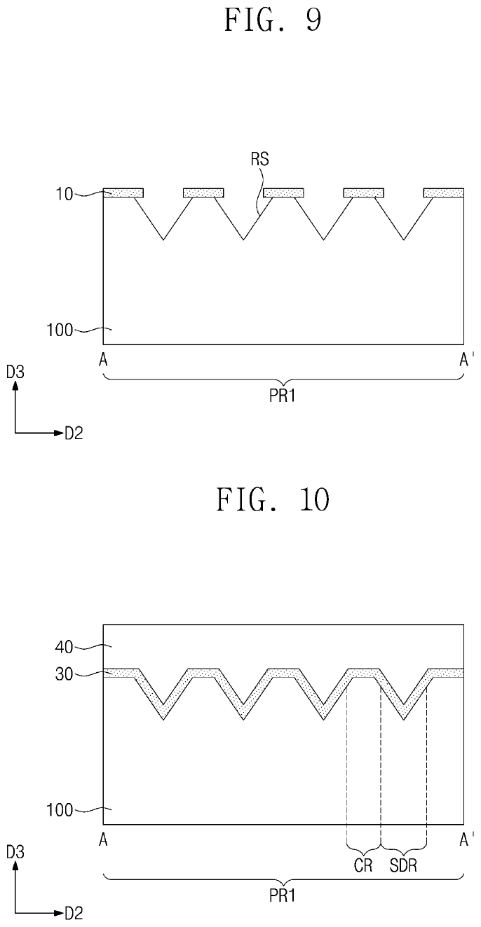

Referring to FIG. 9, an additional etching process may be performed. For example, the etching process may use NH₄OH or KOH to etch the substrate 100. For example, in the etching process that uses NH₄OH or KOH, the substrate 100 may be etched only in a <111> direction (the crystal direction of the crystalline substrate 100). Therefore, the substrate 100 adjacent and below the patterns of the mask layer 10 may be partially additionally removed. Upper portions of the substrate 100 may be removed to form recesses RS. In this description, the recess RS is illustrated to have a triangular shape that is sharp toward a bottom surface of the substrate 100, but may have various shapes, such as shapes corresponding to the shapes of the buried layer OL as discussed in FIGS. 6A to 6E. It will thus be appreciated that this method of fabricating a semiconductor device also applies to the fabrication of the devices discussed I FIGS. 6A to 6E as appropriately modified to provide different shaped recesses RS.

Referring to FIG. 10, a sacrificial layer 30 may be formed to have a constant thickness on the substrate 100. A semiconductor layer 40 may be formed on the sacrificial layer 30. Before the formation of the sacrificial layer 30, the mask layer 10 may be removed. The sacrificial layer 30 may be formed by, for example, an epitaxial growth process. The epitaxial growth process may include a chemical vapor deposition (CVD) process or a molecular beam epitaxy (MBE) process. The sacrificial layer 30 may be, for example, silicon-germanium (SiGe). Likewise, the sacrificial layer 30, the semiconductor layer 40 may be crystalline and may also be formed by an epitaxial growth process. The semiconductor layer 40 may be formed of, for example, silicon (Si). The semiconductor layer 40 may be formed of a semiconductor material that is the same or substantially the same as that of the substrate 100. After the formation of the semiconductor layer 40, a planarization process may be performed. The planarization process of the semiconductor layer 40 may be performed using an etch-back or chemical mechanical polishing (CMP) process.

Referring to FIGS. 4 and 11A to 11C, the substrate 100, the semiconductor layer 40, and the sacrificial layer 30 may be patterned to form first and second active patterns AP1 and AP2 on the substrate 100 and to also form first and second trenches TR1 and TR2 that define the first and second active patterns AP1 and AP2. The first active patterns AP1 may be formed with each of first and second PMOSFET regions PR1 and PR2. The second active patterns AP2 may be formed with each of first and second NMOSFET regions NR1 and NR2. First trenches TR1 may be formed between neighboring first active patterns AP1 and between neighboring second active patterns AP2. The second trench TR2 may be formed between the first NMOSFET region NR1 and the first PMOSFET region PR1, between the first PMOSFET region PR1 and the second PMOSFET region PR2, and between the second PMOSFET region PR2 and the second NMOSFET region NR2 (and surround and isolate the active regions of the same).

After the formation of the first and second active patterns AP1 and AP2, a device isolation layer ST may fill the first and second trenches TR1 and TR2. The device isolation layer ST may include a dielectric material, such as a silicon oxide layer. The device isolation layer ST may be recessed (etched back) until an upper portion of each of the first and second active patterns AP1 and AP2 is exposed. Therefore, the first and second active patterns AP1 and AP2 may have their upper portions that vertically protrude upwardly from the upper surface of the device isolation layer ST. The device isolation layer ST may have a recessed top surface at the same level as or lower than a bottom surface of the sacrificial layer 30.

After the formation of the device isolation layer ST, sacrificial patterns PP may be formed to run across the first and second active patterns AP1 and AP2. Each of the sacrificial patterns PP may be formed to have a linear or bar shape that extends in the first direction D1. The sacrificial patterns PP may correspond to locations in which gate electrodes GE are later formed (as described below).

For example, the formation of the sacrificial patterns PP may include forming a first sacrificial layer on the semiconductor layer 40, forming hardmask patterns MA on the first sacrificial layer, and using the hardmask patterns MA as an etching mask to pattern the first sacrificial layer. The first sacrificial layer may include polysilicon. The patterning process for forming the sacrificial patterns PP may be a lithography process that uses an extreme ultraviolet (EUV) used for forming the photoresist pattern of FIG. 7. Alternatively, the EUV may not be used, but a multi-patterning technique (MPT) may be employed to form the sacrificial patterns PP.

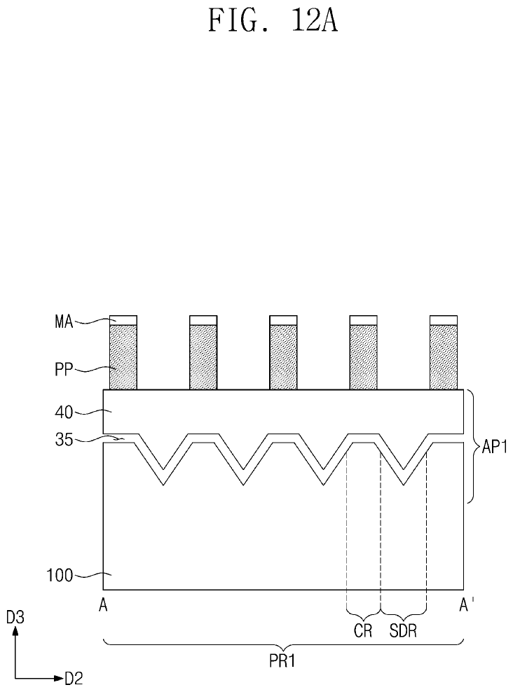

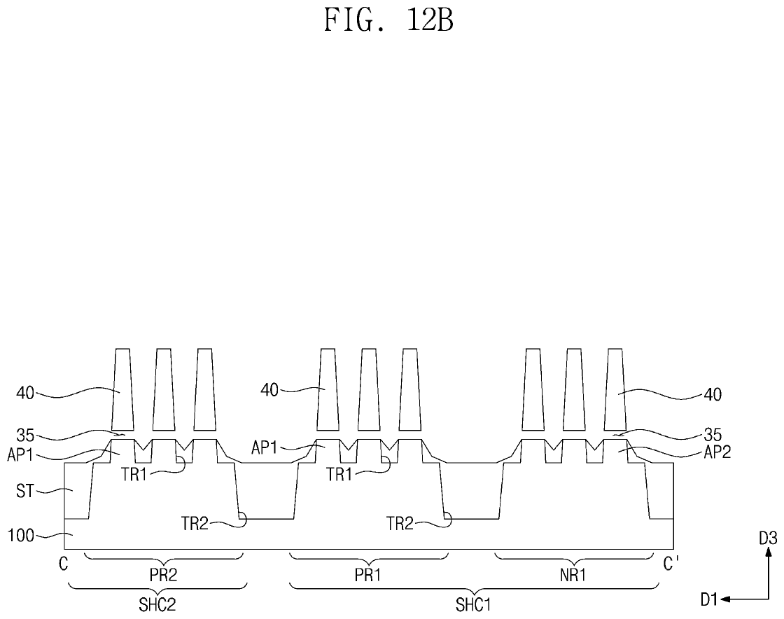

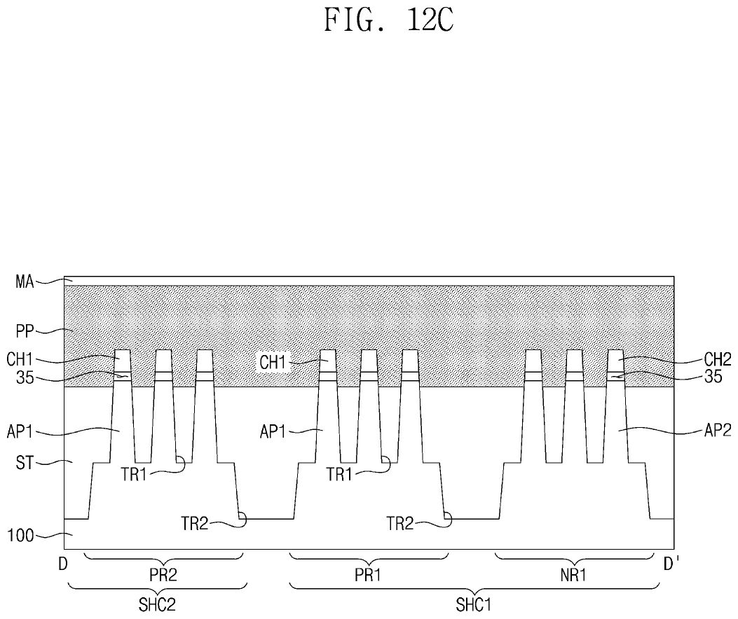

Referring to FIGS. 12A to 12C, the sacrificial layer 30 may be removed through the first and second trenches TR1 and TR2 at source/drain region locations SDR. The sacrificial layer 30 may include a material having an etch selectivity with respect to the substrate 100 and the semiconductor layer 40, and thus an etching process may be performed to remove only the sacrificial layer 30. The sacrificial patterns PP may support the semiconductor layer 40 including the first and second channel patterns CH1 and CH2. After the removal of the sacrificial layer 30, a buried dielectric space 35 may be provided. The buried dielectric space 35 may be provided in and extend through the first and second active patterns AP1 and AP2. The buried dielectric space 35 may be positioned between the substrate 100 and the semiconductor layer 40.

Referring to FIGS. 13A to 13C, there may be formed a buried layer OL, first and second source/drain patterns SD1 and SD2, and gate spacers GS.

The formation of the gate spacers GS may include conformally forming a gate spacer layer on an entire surface of the substrate 100 and anisotropically etching the gate spacer layer. The gate spacer layer may include at least one selected from SiCN, SiCON, and SiN. Although not shown, each of the gate spacers GS may have a multi-layered structure including a first gate spacer and a second gate spacer. The first gate spacer may be formed of SiOCN or a low-k dielectric material. The second gate spacer may be formed of a material different from that of the first gate spacer, such as SiN, and have excellent resistance to etching (e.g., better than that of the first gate spacer). The first gate spacer may be formed thicker than the second gate spacer.

A dielectric material may be deposited in the buried dielectric space 35 to form the buried layer OL. The buried layer OL may include first segments P1 at a source/drain region locations SDR and second segments P2 at channel region locations CR as described elsewhere herein. The dielectric material may include at least one selected from SiCN, SiOCN, and SiN. The formation of the buried layer OL may be performed simultaneously with the formation of the gate spacers GS. For example, the deposition of the dielectric material in the buried dielectric space 35 may be performed simultaneously with the conformal formation of the gate spacer layer (they may be formed from the same deposited layer). In this case, the gate spacer layer may also be conformally formed in the buried dielectric space 35 to form the buried layer OL. The buried layer OL and the gate spacers GS may be formed of the same dielectric material. Therefore, a simple process may be achieved. Alternatively, when each of the gate spacers GS has a multi-layered structure including a first gate spacer and a second gate spacer, the formation of the first gate spacer layer may be performed simultaneously with the deposition of the dielectric material in the buried dielectric space 35 (the first gate spacer and the buried layer OL may be formed of the same layer). For example, the second gate spacer may not form a portion of the buried layer OL.

First source/drain patterns SD1 may be formed on an upper portion of each of the first active patterns AP1. A pair of first source/drain patterns SD1 may be formed on opposite sides of each of the sacrificial patterns PP. For example, the mask patterns MA and the gate spacers GS may be used as an etching mask to etch the upper portions of the first active patterns AP1 to form first recesses in the first active patterns AP1.

The first source/drain pattern SD1 may be formed by performing a selective epitaxial growth process in which an inner wall of the first recess of the first active pattern AP1 is used as a seed layer. The formation of the first source/drain patterns SD1 may define a first channel pattern CH1 between a pair of first source/drain patterns SD1. For example, the selective epitaxial growth process may include a chemical vapor deposition (CVD) process or a molecular beam epitaxy (MBE) process. The first source/drain patterns SD1 may be formed of a crystalline semiconductor material (e.g., SiGe) whose lattice constant is greater than that of the crystalline semiconductor material of the substrate 100. Each of the first source/drain patterns SD1 may be formed of a plurality of stacked semiconductor layers.

For example, charge carrier impurities may be in-situ implanted during the selective epitaxial growth process for forming the first source/drain patterns SD1. In other examples, after the formation of the first source/drain patterns SD1, charge carrier impurities may be implanted into the first source/drain patterns SD1. The first source/drain patterns SD1 may be doped to have a first conductivity type (e.g., p-type).

Second source/drain patterns SD2 may be formed on an upper portion of the second active pattern AP2. A pair of second source/drain patterns SD2 may be formed on opposite sides of each of the sacrificial patterns PP. For example, the mask patterns MA and the gate spacers GS may be used as an etching mask to etch the upper portion of the second active pattern AP2 to form second recesses. The second source/drain pattern SD2 may be formed by performing a selective epitaxial growth process in which an inner wall of the second recess of the second active pattern AP2 is used as a seed layer. The formation of the second source/drain patterns SD2 may define a second channel pattern CH2 between a pair of second source/drain patterns SD2. For example, the second source/drain patterns SD2 may be formed of the same semiconductor material (e.g., crystalline Si) as that of the substrate 100. The second source/drain patterns SD2 may be doped to have a second conductivity type (e.g., n-type).

Different processes may be performed to sequentially form the first source/drain patterns SD1 and the second source/drain patterns SD2. The first and second source/drain patterns SD1 and SD2 may not be formed at the same time.

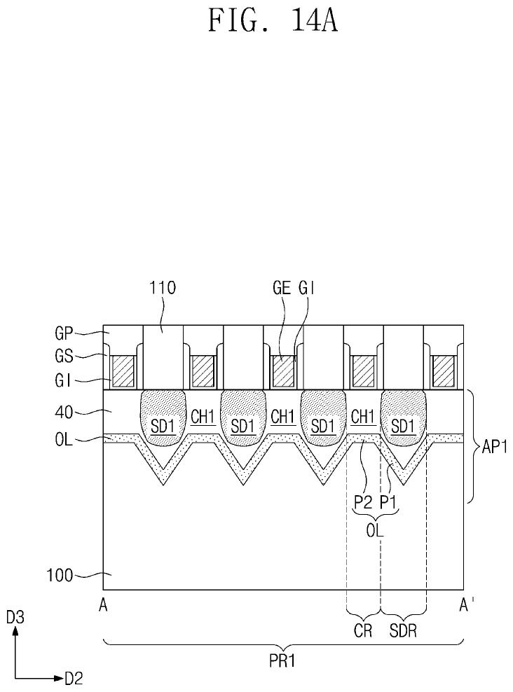

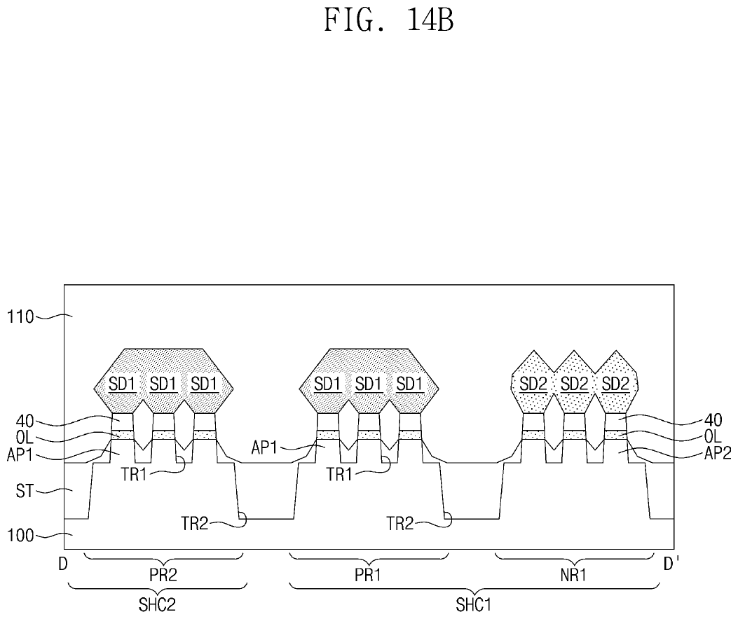

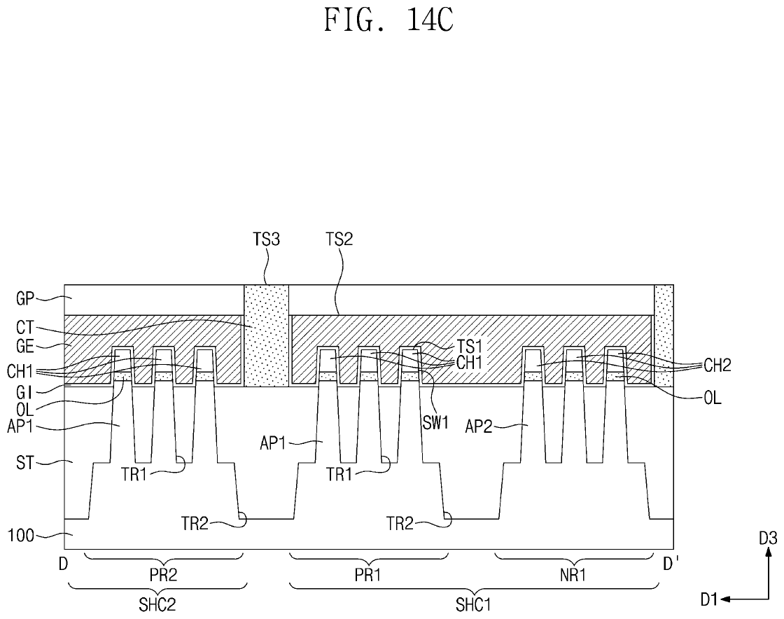

Referring to FIGS. 14A to 14C, a first interlayer dielectric layer 110 may be formed to cover the first and second source/drain patterns SD1 and SD2. A gate capping pattern GP may be formed to cover the gate spacers GS and to also cover a gate electrode GE and a gate dielectric layer GI which are discussed below. A gate cutting pattern CT may be formed to allow the gate electrode GE to be cut in the first direction D1.

After the formation of the first interlayer dielectric layer 110, the first interlayer dielectric layer 110 may be planarized until top surfaces of the sacrificial patterns PP are exposed. An etch-back or chemical mechanical polishing (CMP) process may be employed to planarize the first interlayer dielectric layer 110. The mask patterns MA may all be removed during the planarization process. As a result, the first interlayer dielectric layer 110 may have a top surface coplanar with those of the sacrificial patterns PP and those of the gate spacers GS.

A plurality of gate cutting patterns CT may be formed on a boundary parallel to the second direction D2 of each of the first and second single height cells SHC1 and SHC2 depicted in FIG. 4. For example, a mold layer may be formed on the recessed sacrificial pattern PP. A photolithography process may be used to form a mask layer including openings that define locations on which the gate cutting patterns CT will be formed in the mold layer. An etching process may be used to selectively remove the mold layer and its underlying sacrificial pattern PP that are exposed by the opening. A dielectric material may fill the area removed the mold layer and its underlying sacrificial pattern PP, thereby forming the gate cutting pattern CT.

The sacrificial patterns PP may be replaced with the gate electrodes GE. For example, the exposed sacrificial pattern PP may be selectively removed to form an empty space. The gate dielectric layer GI and the gate electrode GE may be formed in the empty space.

The gate dielectric layer GI may contact the first and second channel patterns CH1 and CH2 that are exposed by the empty spaces. The formation of the gate dielectric layer GI may include forming a silicon oxide layer on the first and second channel patterns CH1 and CH2, and forming a high-k dielectric layer on the silicon oxide layer.

The gate electrode GE may be formed on the gate dielectric layer GI. The gate electrode GE may include a first metal pattern and a second metal pattern on the first metal pattern. The first metal pattern may be formed of a work-function metal capable of controlling a threshold voltage of a transistor, and the second metal pattern may be formed of metal whose resistance is low.

The gate capping pattern GP may be formed on the gate electrode GE and the gate dielectric layer GI that are recessed. The gate capping pattern GP may cover a recessed top surface of the gate electrode GE and a recessed top surface of the gate spacer GS. The gate capping pattern GP may have a top surface coplanar with those of the gate cutting patterns CT. The gate capping patterns GP may be formed of one or more of SiON, SiCN, SiCON, and SiN.

Referring back to FIGS. 4 and 5A to 5E, a second interlayer dielectric layer 120 may be formed on the first interlayer dielectric layer 110. The second interlayer dielectric layer 120 may include a silicon oxide layer. A pair of separation structures DB may be formed on opposite sides of the first single height cell SHC1. The separation structures DB may be formed to overlap the gate electrodes GE formed on the opposite sides of the first single height cell SHC1. For example, the formation of the separation structures DB may include forming a hole that penetrates the first and second interlayer dielectric layers 110 and 120 and extends into the first and second active patterns AP1 and AP2, and then filling the hole with a dielectric layer.

Active contacts AC may be formed to penetrate the second and first interlayer dielectric layers 120 and 110 and to electrically connect to the first and second source/drain patterns SD1 and SD2. A gate contact GC may be formed to penetrate the second interlayer dielectric layer 120 and the gate capping pattern GP to contact and electrically connect to the gate electrode GE.

A third interlayer dielectric layer 130 may be formed on the second interlayer dielectric layer 120. A first metal layer M1 may be formed in the third interlayer dielectric layer 130. The formation of the first metal layer M1 may include forming a first power line M1_R1, a second power line M1_R2, a third power line M1_R3, and first wiring lines M1_I.

A fourth interlayer dielectric layer 140 may be formed on the first metal layer M1. A second metal layer M2 may be formed in the fourth interlayer dielectric layer 140. The formation of the second metal layer M2 may include forming second wiring lines M2_I. The second wiring lines M2_I may be formed by, for example, a dual damascene process.

According to an embodiment of the present inventive concepts, the formation of the wiring lines in the first and second metal layers M1 and M2 may include performing a lithography process that uses an extreme ultraviolet (EUV) exposure process. The EUV lithography process used in forming of the wiring lines, or a back-end-of-line (BEOL) process, may be substantially the same as that for forming the sacrificial patterns PP. For example, a distance equal to or less than about 45 nm may be given as a minimum pitch between the first wiring lines M1_I formed by the EUV lithography process.

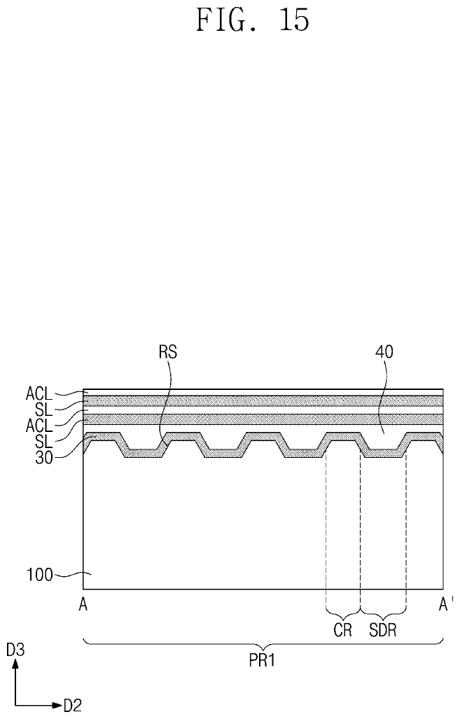

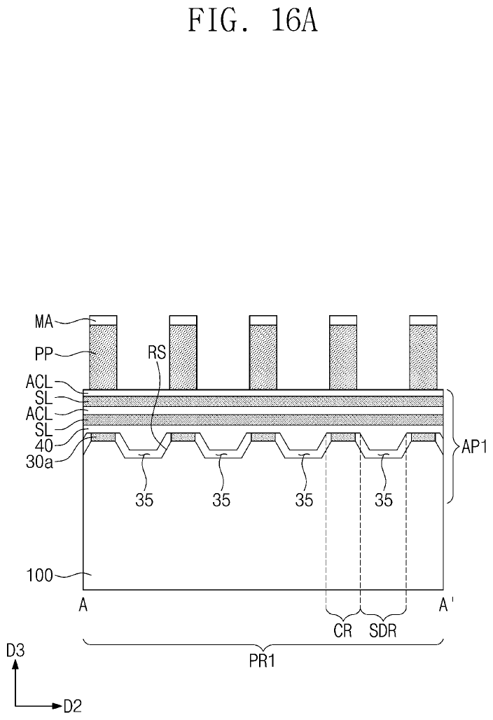

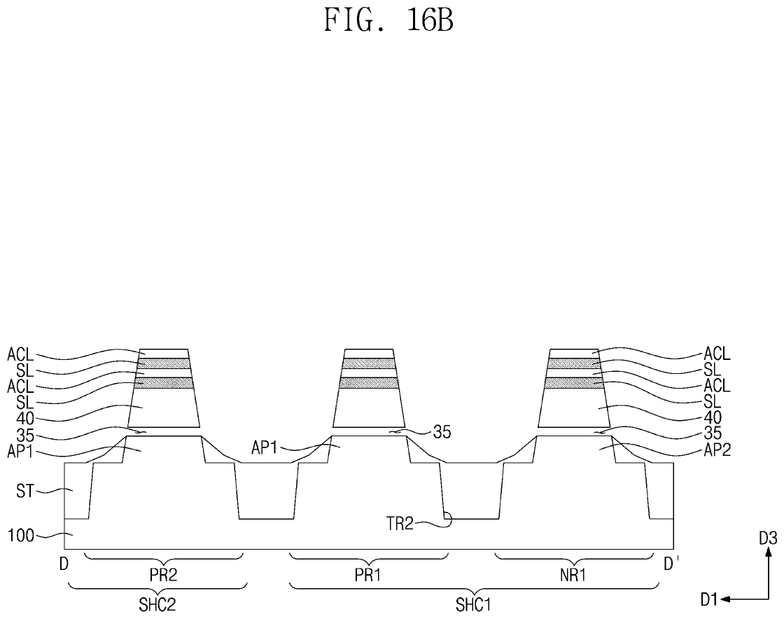

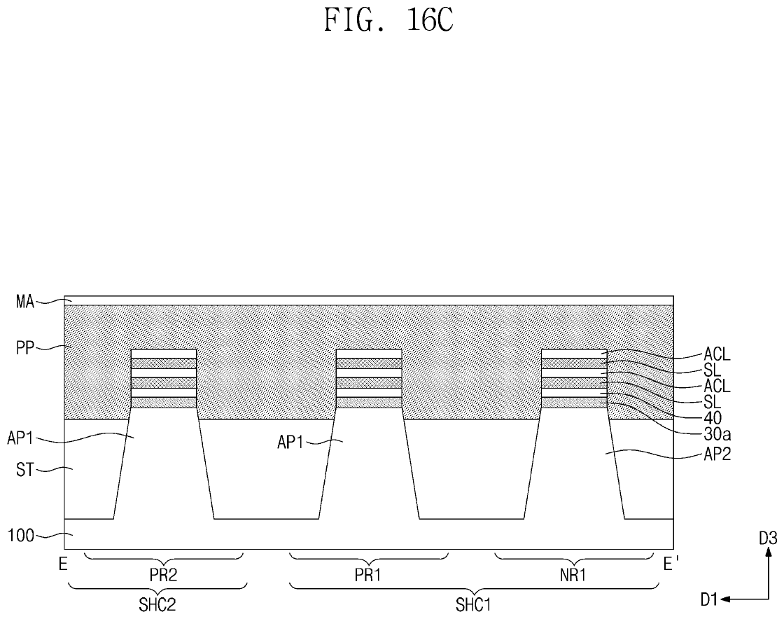

FIGS. 15 to 18C illustrate cross-sectional views showing a method of fabricating a semiconductor device according to some embodiments of the present inventive concepts. FIGS. 15, 16A, 17A, and 18A illustrate cross-sectional views taken along line A-A′ of FIG. 4. FIGS. 16B, 17B, and 18B illustrate cross-sectional views taken along line C-C′ of FIG. 4. FIGS. 16C, 17C, and 18C illustrate cross-sectional views taken along line D-D′ of FIG. 4.

For convenience of description, a description of the same components as those discussed with reference to FIGS. 7 to 14C may be omitted below, and a difference thereof will be discussed in detail.

Referring to FIG. 15, like that discussed in FIGS. 7 to 9, portions of the substrate 100 may be etched to form a recess RS, and a shape of the recess RS may be variously changed. After the formation of the recess RS, a sacrificial layer 30 and a semiconductor layer 40 may be formed. The sacrificial layer 30 may be a conformal layer that has a constant thickness. The sacrificial layer 30 and the semiconductor layer 40 may be formed by, for example, an epitaxial growth process. The epitaxial growth process may include a chemical vapor deposition (CVD) process or a molecular beam epitaxy (MBE) process. The semiconductor layer 40 may be formed and then a planarization process may be performed. The planarization process of the semiconductor layer 40 may be performed by using an etch-back or chemical mechanical polishing (CMP) process. Support layers SL and active layers ACL may be alternately formed on the semiconductor layer 40. In this case, the sacrificial layer 30 may be vertically spaced apart from a lowermost one of the support layers SL.

The active layers ACL and the semiconductor layer 40 may be formed of a crystalline semiconductor material, such as being formed of one or more of silicon (Si), germanium (Ge), and silicon-germanium (SiGe), for example, crystalline silicon. The sacrificial layer 30 and the support layers SL may be formed of a semiconductor material, such as silicon (Si), germanium (Ge), and silicon-germanium (SiGe), for example, silicon-germanium (SiGe). The sacrificial layer 30 and the support layers SL may include a material having an etch selectivity with respect to the active layers ACL and the semiconductor layer 40. The sacrificial layer 30 and the support layers SL may each have a germanium concentration ranging from about 10 at % to about 30 at %. The germanium concentration of the sacrificial layer 30 may be greater than that of the support layers SL.

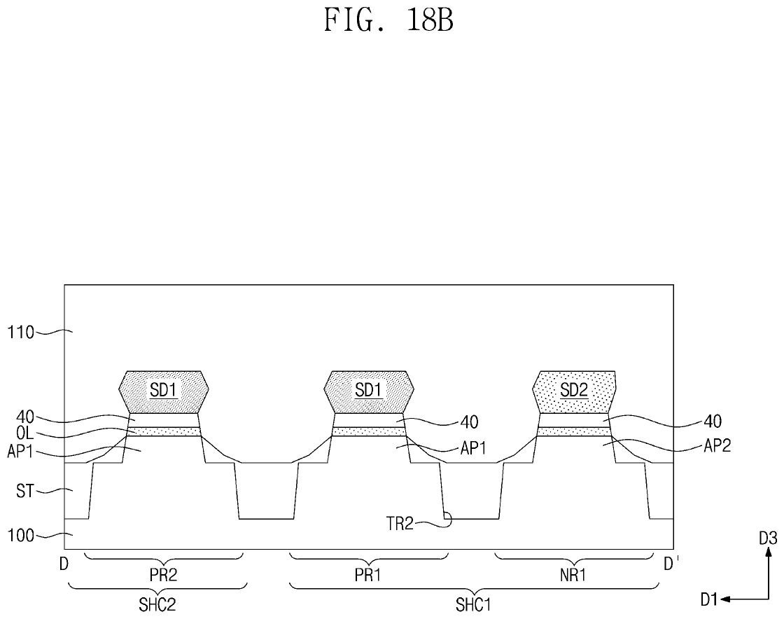

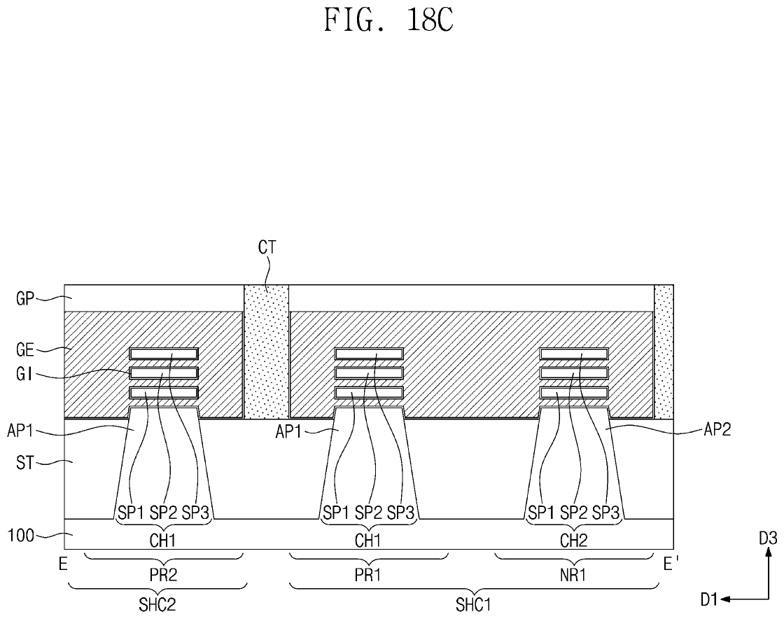

Referring to FIGS. 16A to 16C, the removal of the sacrificial layer 30 may be the same as that discussed in FIGS. 12A to 12C. However, the etching process for removing a portion of the sacrificial layer 30 may be performed for a duration less than that required for the etching process discussed in FIGS. 12A to 12C. Thus, the sacrificial layer 30 at the source/drain region locations SDR may be removed, and the sacrificial layer 30 at the channel region locations CR may not be removed (or at least not fully removed). The sacrificial layer 30 at the source/drain region locations SDR may be removed to provide a buried dielectric spaces 35. However, the sacrificial layer 30 at the channel region locations CR may remain to form patterned sacrificial layer 30a. As the germanium concentration of the sacrificial layer 30 is greater than that of the support layers SL, the support layers SL may not be etched (or not significantly etched). Differently from that discussed in FIGS. 7 to 14C, the patterned sacrificial layer 30a may be replaced with a conductive material in a subsequent process and may serve as a gate of a transistor (see FIG. 18A).

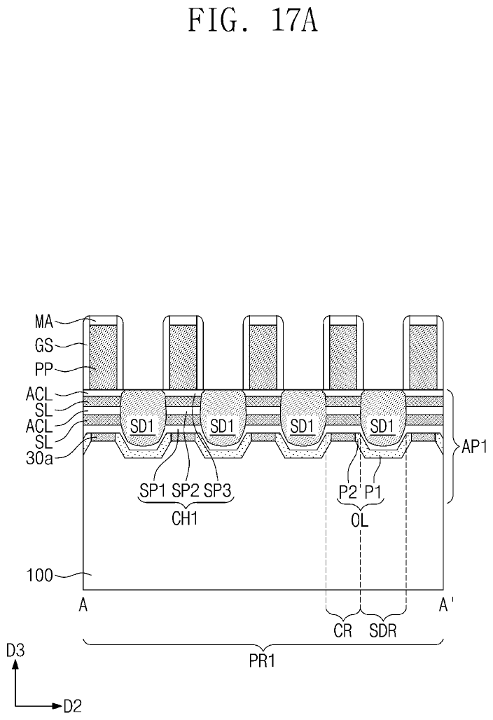

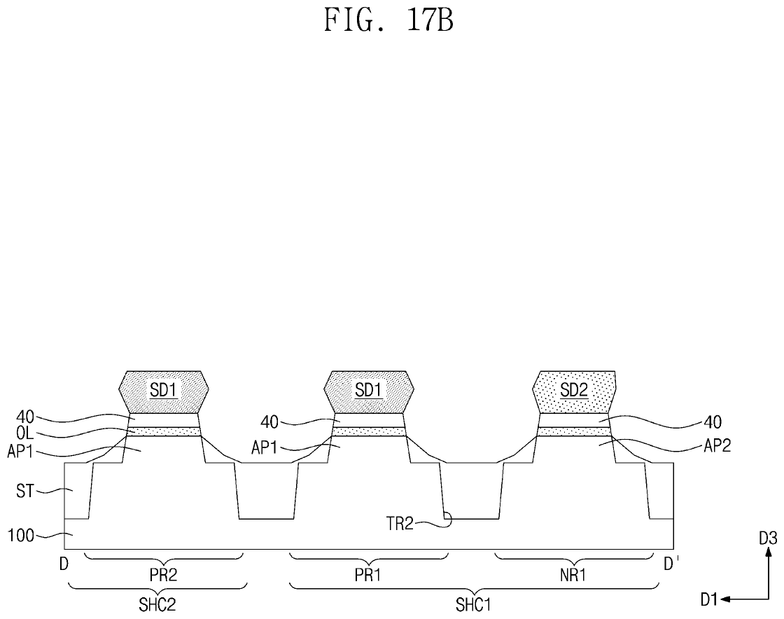

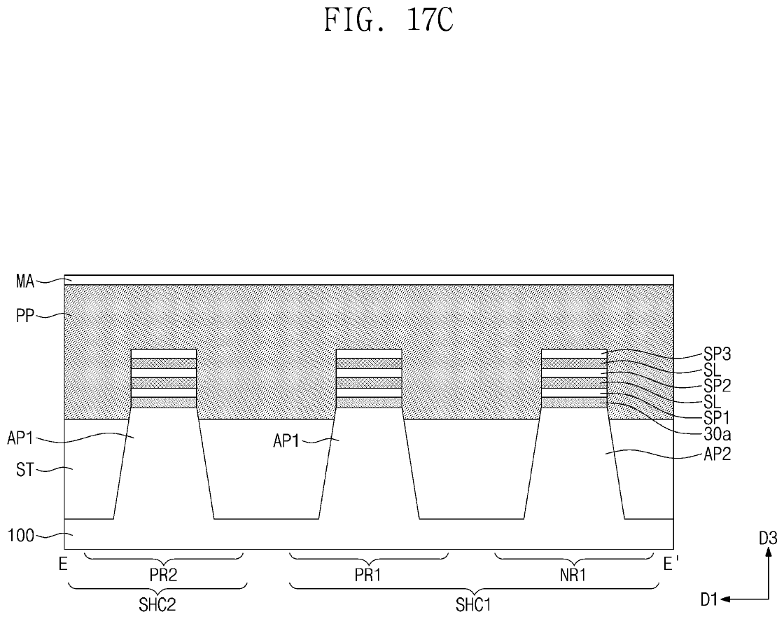

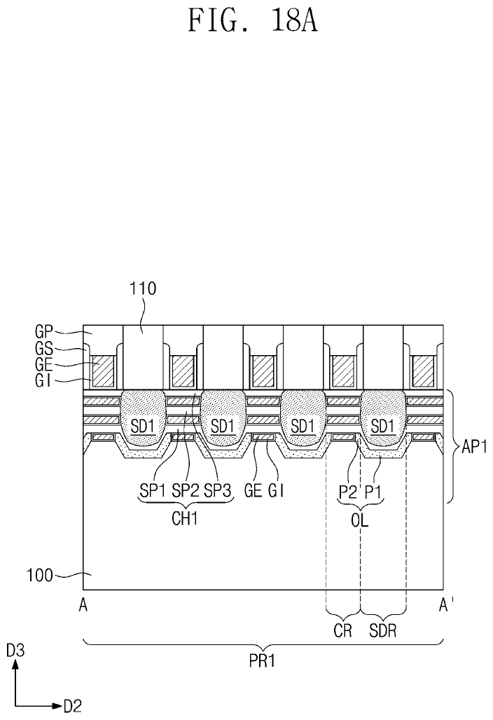

Referring to FIGS. 17A to 17C, sacrificial patterns PP, mask patterns MA, and gate spacers GS may be provided on an uppermost one of the active layers ACL. First and second source/drain patterns SD1 and SD2 may be provided between the sacrificial patterns PP.

The formation of the sacrificial patterns PP and the mask patterns MA may be the same as that discussed in FIGS. 11A to 11C. The formation of the gate spacers GS and the first and second source/drain patterns SD1 and SD2 may be the same as that discussed in FIGS. 12A to 12C. Similarly, the buried layer OL may be formed simultaneously with the formation of the gate spacers GS in the same deposition process, and be formed of the same layer and same material.

Differently from that discussed in FIGS. 13A to 13C, as the buried dielectric space (see 35 of FIG. 16A) is provided in the source/drain region locations SDR but the patterned sacrificial layer 30a remains in the channel region locations CR, the first segments P1 may be formed of a dielectric material while the second segments P2 may be formed of a different material (e.g., a conductive material). For example, the first segments P1 may be formed of the same dielectric material as that of the gate spacers GS while second segments P2 may not include a dielectric material.

The semiconductor layer 40 and the active layers ACL at the channel region locations CR may be formed into first, second, and third semiconductor patterns SP1, SP2, and SP3. The first, second, and third semiconductor patterns SP1, SP2, and SP3 may form the first channel pattern CH1.

Referring to FIGS. 18A to 18C, a first interlayer dielectric layer 110 may be formed, a gate electrode GE may be formed, and then a gate capping pattern GP may be formed. The formation of the first interlayer dielectric layer 110 and the gate capping pattern GP may be the same as that discussed in FIGS. 14A to 14C.

After the formation of the first interlayer dielectric layer 110, sacrificial patterns PP may be removed. After the removal of the sacrificial patterns PP, the patterned sacrificial layer 30a and the support layers SL may be removed. For example, an etching process that selectively etches the patterned sacrificial layer 30a and the support layers SL may be performed such that only the patterned sacrificial layer 30a and the support layers SL may be removed, and such that the first, second, and third semiconductor patterns SP1, SP2, and SP3 may remain. The etching process may have a high etch rate with respect to silicon-germanium (SiGe) whose germanium concentration is relatively high. For example, the etching process may have a high etch rate with respect to silicon-germanium (SiGe) having a germanium concentration greater than about 10 at %.

A gate dielectric layer GI may be conformally formed on surfaces in the voids resulting from the removal of (i.e., previously occupied by) the patterned sacrificial layer 30a and the support layers SL. The gate dielectric layer GI may be provided on the first, second, and third semiconductor patterns SP1, SP2, and SP3. A gate electrode GE may be formed on the gate dielectric layer GI. For example, the patterned sacrificial layer 30a and the support layers SL may be removed and replaced with the gate dielectric layer GI and the gate electrode GE. The second segment P2 of the buried layer OL may include a portion of the gate electrode GE and a portion of the gate dielectric layer GI surrounding that portion of the gate electrode GE.

Afterwards, there may be formed second, third, and fourth interlayer dielectric layers 120, 130, and 140, first and second metal layers M1 and M2, active contacts AC, and gate contacts GC, and the formation thereof may be the same as that discussed above.

A semiconductor device according to some embodiments of the present inventive concepts may include a buried layer below a field effect transistor. The buried layer may be positioned lower at a source/drain region location SDR than at a channel region location CR, and thus a source/drain pattern may be formed deeper than a channel pattern and have a greater vertical length than a channel pattern. Thus, a leakage current may be reduced to increase performance of the semiconductor device.

In a method of fabricating a semiconductor device according to some embodiments of the present inventive concepts, a sacrificial layer may be first formed which is provided below a source/drain pattern of a field effect transistor. The sacrificial layer may be replaced with a buried layer at the same time that a gate spacer layer is deposited on a substrate (e.g., formed with the same deposited material in the same deposition process). Accordingly, a simple process may be achieved, and a leakage current may be reduced to increase performance of the semiconductor device.

While certain detailed examples of the present inventive concepts have been particularly shown and described, it will be apparent to those skilled in the art that various changes in form and details may be made therein without departing from the spirit and scope of the inventive concepts as set forth in the following claims.

Although the present invention has been described in connection with the embodiments of the present invention illustrated in the accompanying drawings, it will be understood to those skilled in the art that various changes and modifications may be made without departing from the technical spirit and essential feature of the present invention. It therefore will be understood that the embodiments described above are exemplary but not limitative in all aspects.

What is claimed is:

1. A semiconductor device, comprising:
a substrate provided with an active pattern;
a gate electrode that runs across the active pattern and extends in a first direction;
source/drain patterns on the active pattern on opposite sides of the gate electrode;
a channel pattern between the source/drain patterns and in the active pattern; and
a buried layer below the source/drain patterns and the channel pattern,
wherein the buried layer includes:
first segments below the source/drain patterns; and
a second segment below the channel pattern,
wherein the first segments have a first level,
wherein the second segment has a second level, and
wherein the first level is lower than the second level.

2. The semiconductor device of claim 1, wherein
the first level of the first segments is the average distance between the first segments and a bottom surface of the substrate, and
the second level of the second segment is the average distance between the second segment and the bottom surface of the substrate.

3. The semiconductor device of claim 1, wherein the first segments of the buried layer have inclined surfaces relative to a horizontal direction and have a wedge shape whose width decreases with respect to an increasing distance in a vertical direction away from the source/drain patterns.

4. The semiconductor device of claim 1, wherein the second segment of the buried layer has a convex shape directed toward the gate electrode.

5. The semiconductor device of claim 1, wherein the first segments of the buried layer have a first thickness that is less than a second thickness of the second segment of the buried layer.

6. The semiconductor device of claim 1, further comprising a pair of gate spacers on opposite sidewalls of the gate electrode,
wherein top surfaces of the pair of gate spacers are higher than a top surface of the gate electrode.

7. The semiconductor device of claim 6, wherein the pair of gate spacers and the buried layer are formed of the same dielectric material layer.

8. The semiconductor device of claim 1, wherein the buried layer is spaced apart from the source/drain patterns.

9. The semiconductor device of claim 1, wherein a distance in a vertical direction between the gate electrode and the buried layer is less than a vertical length of the source/drain patterns.

10. The semiconductor device of claim 1, wherein
the first segments of the buried layer are formed of a dielectric material, and
the second segment of the buried layer and the gate electrode are formed of the same conductive material.

11. The semiconductor device of claim 10, wherein the gate electrode surrounds the channel pattern.

12. The semiconductor device of claim 11,
wherein the channel pattern includes a first semiconductor pattern, a second semiconductor pattern, and a third semiconductor pattern, and
wherein the first to third semiconductor patterns are spaced apart from each other in a vertical direction.

13. The semiconductor device of claim 12, wherein respective portions of the gate electrode are formed between the first semiconductor pattern and the second semiconductor pattern and between the second semiconductor pattern and the third semiconductor pattern.

14. The semiconductor device of claim 13, further comprising a gate dielectric layer between the portions of the gate electrode and the first to third semiconductor patterns.

15. A semiconductor device, comprising:
a substrate provided with a logic cell including a PMOSFET region and an NMOSFET region that are spaced apart from each other in a first direction;
a device isolation layer on the substrate;
a first active pattern in the PMOSFET region and a second active pattern in the NMOSFET region, the first and second active patterns extending in a second direction, and an upper portion of each of the first and second active patterns protruding upwardly above the device isolation layer;
a gate electrode that extends in the first direction and runs across the first and second active patterns;
first source/drain patterns on the first active pattern;
second source/drain patterns on the second active pattern;
a first channel pattern between the first source/drain patterns;
a second channel pattern between the second source/drain patterns;
a buried layer below the first and second source/drain patterns and below the first and second channel patterns;
a pair of gate spacers on opposite sidewalls of the gate electrode, the pair of gate spacers extending in the first direction;
a gate dielectric layer on a bottom surface and side surfaces of the gate electrode;
an interlayer dielectric layer on the gate electrode and the gate spacers;
an active contact that penetrates the interlayer dielectric layer and is electrically connected to at least one of the first and second source/drain patterns; and
a gate contact that penetrates the interlayer dielectric layer and is electrically connected to the gate electrode,
wherein the buried layer includes:
first segments below the first and second source/drain patterns; and
second segments below the first and second channel patterns,
wherein the first segments have a first level,
wherein the second segments have a second level, and
wherein the first level is lower than the second level.

16. The semiconductor device of claim 15, wherein
the buried layer has a constant thickness, and
wherein the first segments of the buried layer have an inclined surface relative to the substrate and have a wedge shape whose width decreases with increasing distance in a vertical direction from the first and second source/drain patterns.

17. The semiconductor device of claim 15, wherein the gate spacers and the buried layer are formed of the same dielectric material layer.

18. A method of fabricating a semiconductor device, the method comprising:
patterning a substrate to form a plurality of recesses in the surface of the substrate;
forming a sacrificial layer on the substrate including in the plurality of recesses;
forming a semiconductor layer on the sacrificial layer;
patterning the semiconductor layer to form active patterns;
forming sacrificial patterns that run across the active patterns and extend in a first direction;
forming a corresponding pair of gate spacers on opposite sidewalls of each of the sacrificial patterns;
replacing the sacrificial layer with a buried layer;
replacing the sacrificial patterns with a gate electrode; and
forming source/drain patterns on the active patterns,
wherein forming the pair of gate spacers and replacing the sacrificial layer with the buried layer are performed at the same time.

19. The method of claim 18, wherein replacing the sacrificial layer with the buried layer includes:
removing the sacrificial layer to provide a buried dielectric space between the substrate and the source/drain patterns; and
depositing a dielectric material in the buried dielectric space.

20. The method of claim 19,
wherein removing the sacrificial layer as part of replacing the sacrificial layer with the buried layer comprises removing only a portion of the sacrificial layer to form a patterned sacrificial layer.
